(19) United States
(12) Patent Application Publication
(10) Pub. No.: US 2025/0078929 A1
(43) Pub. Date: Mar. 6, 2025

(54) SEMICONDUCTOR DEVICE AND ELECTRONIC SYSTEM INCLUDING THE SAME

(71) Applicant: Samsung Electronics Co., Ltd., Suwon-si (KR)

(72) Inventors: Kibong MOON, Suwon-si (KR); Suck-Soo KIM, Suwon-si (KR); Tae Hun KIM, Suwon-si (KR); Hyoje BANG, Suwon-si (KR); Seung Jae BAIK, Suwon-si (KR); Sung-Bok LEE, Suwon-si (KR); Jaeduk LEE, Suwon-si (KR); Junhee LIM, Suwon-si (KR)

(73) Assignee: Samsung Electronics Co., Ltd., Suwon-si (KR)

(21) Appl. No.: 18/679,809

(22) Filed: May 31, 2024

(30) Foreign Application Priority Data
Aug. 30, 2023 (KR) 10-2023-0114192

(51) Int. Cl. G11C 16/04; G11C 5/06; H01L 25/065; H10B 41/10; H10B 41/27; H10B 41/35; H10B 41/41; H10B 43/10; H10B 43/27; H10B 43/35; H10B 43/40; H10B 80/00

(52) U.S. Cl. CPC G11C 16/0483; G11C 5/063; H01L 25/0652; H10B 41/10; H10B 41/27; H10B 41/35; H10B 41/41; H10B 43/10; H10B 43/27; H10B 43/35; H10B 43/40; H10B 80/00; H01L 2225/06506

(57) ABSTRACT

A semiconductor device may include a substrate, a plurality of cell strings perpendicular to an upper surface of the substrate, and a bit line connected to at least six of the cell strings. Each of the cell strings may include a plurality of memory cells connected in series to each other in a direction perpendicular to the upper surface of the substrate, first to fourth ground selection transistors connected in series to each other between the plurality of memory cells and the substrate, and a string selection transistor between the plurality of memory cells and the bit line. A first one of the first to fourth selection ground selection transistors may have a first threshold voltage distribution, and a second one of the first to fourth ground selection transistors may have a second threshold voltage distribution. The second threshold voltage distribution may be different from the first threshold voltage distribution.

### CROSS-REFERENCE TO RELATED APPLICATIONS

This U.S. non-provisional patent application claims priority under 35 U.S.C. § 119 to Korean Patent Application No. 10-2023-0114192, filed on Aug. 30, 2023, in the Korean Intellectual Property Office, the entire contents of which are hereby incorporated by reference.

### BACKGROUND

Inventive concepts relate to a semiconductor device and an electronic system including the same.

In an electronic system requiring data storage, a semiconductor device capable of storing high-capacity data may be required. Accordingly, methods for increasing data storage capacity of semiconductor devices are being studied. For example, as a method for increasing data storage capacity of a semiconductor device, a semiconductor device including memory cells arranged three-dimensionally, instead of memory cells arranged two-dimensionally, has been proposed.

### SUMMARY

Some example embodiments provide a semiconductor device with improved reliability and integration.

Some example embodiments provide an electronic system including a semiconductor device.

The present disclosure is not limited to the aspects mentioned above, and other aspects not mentioned will be clearly understood by those skilled in the art from the description below.

According to an example embodiment, a semiconductor device may include a substrate; a plurality of cell strings disposed perpendicular to an upper surface of the substrate; and a bit line connected to at least six of the plurality of cell strings. Each of the plurality of cell strings may include a plurality of memory cells connected in series to each other in a direction perpendicular to the upper surface of the substrate, a first ground selection transistor to a fourth ground selection transistor connected in series to each other between the plurality of memory cells and the substrate, and a string selection transistor between the plurality of memory cells and the bit line. Based on the string selection transistor and the first ground selection transistor to the fourth ground selection transistor in each of the plurality of cell strings, the plurality of cell strings may provide a plurality of string selection transistors, a plurality of first ground selection transistors, a plurality of second ground selection transistors, a plurality of third ground selection transistors, and a plurality of fourth ground selection transistors. The plurality of string selection transistors of the plurality of cell strings may be electrically separated from each other. The plurality of first ground selection transistors in the plurality of cell strings may be configured to be controlled in common. The plurality of second ground selection transistors in the plurality of cell strings may be configured to be controlled in common. The plurality of third ground selection transistors in the plurality of cell strings may be configured to be controlled in common. The plurality of fourth ground selection transistors in the plurality of cell strings may be configured to be controlled in common. A first one of the plurality of first ground selection transistors to the plurality of fourth ground selection transistors may have a first threshold voltage distribution. A second one of the plurality of first ground selection transistors to the plurality of fourth ground selection transistors may have a second threshold voltage distribution. The second threshold voltage distribution may be different from the first threshold voltage distribution.

According to an example embodiment, a semiconductor device may include a substrate; a plurality of cell strings perpendicular to an upper surface of the substrate; and a bit line connected to at least six of the plurality of cell strings. Each of the plurality of cell strings may include a plurality of memory cells connected in series to each other in a direction perpendicular to the upper surface of the substrate, a plurality of ground selection transistors connected in series to each other between the plurality of memory cells and the substrate, and a string selection transistor between the plurality of memory cells and the bit line. In each of the plurality of cell strings, the plurality of ground selection transistors may include a first ground selection transistor having a first threshold voltage distribution, a second ground selection transistor having a second threshold voltage distribution, and a third ground selection transistor having a third threshold voltage distribution. The first threshold voltage distribution, the second threshold voltage distribution, and the third threshold voltage distribution may be different from each other.

According to an example embodiment, an electronic system may include a semiconductor device including a peripheral circuit structure and a cell array structure on the peripheral circuit structure; and a controller electrically connected to the semiconductor device through an input/output pad and configured to control the semiconductor device. The cell array structure may include a substrate, a plurality of cell strings disposed perpendicular to an upper surface of the substrate, and a bit line connected to at least six of the plurality of cell strings. Each of the plurality of cell strings may include a plurality of memory cells connected in series to each other in a direction perpendicular to the upper surface of the substrate, a first ground selection transistor to a fourth ground selection transistor connected in series to each other between the plurality of memory cells and the substrate, and a string selection transistor between the plurality of memory cells and the bit line. Based on the string selection transistor and the first ground selection transistor to the fourth ground selection transistor in each of the plurality of cell strings, the plurality of cell strings may provide a plurality of string selection transistors, a plurality of first ground selection transistors, a plurality of second ground selection transistors, a plurality of third ground selection transistors, and a plurality of fourth ground selection transistors. The plurality of string selection transistors of the plurality of cell strings may be electrically separated from each other. The plurality of first ground selection transistors in the plurality of cell strings may be configured to be controlled in common. The plurality of second ground selection transistors in the plurality of cell strings may be configured to be controlled in common. The plurality of third ground selection transistors in the plurality of cell strings may be configured to be controlled in common. The plurality of fourth ground selection transistors in the plurality of cell strings may be configured to be controlled in common. A first one of the plurality of first ground selection transistors to the plurality of fourth ground selection transistors may have a first threshold voltage distribution. A second one of the plurality of first ground selection transistors to the plurality of fourth ground selection transistors may have a second threshold voltage distribution. The second threshold voltage distribution may be different from the first threshold voltage distribution.

Specific details of other example embodiments are included in the detailed description and drawings.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a diagram schematically illustrating an electronic system including a semiconductor device according to an embodiment of inventive concepts.

FIG. 2 is a perspective view schematically illustrating an electronic system including a semiconductor device according to an embodiment of inventive concepts.

FIGS. 3 and 4 are cross-sectional views schematically illustrating semiconductor packages according to an embodiment of inventive concepts.

FIG. 5 is a schematic block diagram illustrating a memory cell array of a semiconductor device according to embodiments of inventive concepts.

FIG. 6 is a circuit diagram illustrating a memory cell array of a semiconductor device according to embodiments of inventive concepts.

FIGS. 7A and 7B are plan views illustrating a portion of a memory cell array of a semiconductor device according to an embodiment of inventive concepts.

FIG. 8A is a cross-sectional view of a semiconductor device according to an embodiment of inventive concepts.

FIG. 8B is an enlarged view of a portion of a semiconductor device according to an embodiment of inventive concepts.

FIG. 9 is a circuit diagram illustrating a cell array of a semiconductor device according to embodiments of inventive concepts, and illustrates a voltage condition during a read operation.

FIG. 10 is a diagram illustrating a threshold voltage distribution of ground selection transistors in a memory cell array of a semiconductor device according to an embodiment of inventive concepts.

FIG. 11 is a table showing threshold voltages of ground selection transistors in the semiconductor device illustrated in FIG. 9.

FIG. 12 is a circuit diagram illustrating a cell array of a semiconductor device according to embodiments of inventive concepts, and illustrates a voltage condition during a read operation.

FIG. 13 is a table showing threshold voltages of ground selection transistors in the semiconductor device illustrated in FIG. 12.

FIG. 14 is a circuit diagram illustrating a cell array of a semiconductor device according to embodiments of inventive concepts, and illustrates a voltage condition during a read operation.

FIG. 15 is a diagram illustrating a threshold voltage distribution of ground selection transistors in a memory cell array of a semiconductor device according to an embodiment of inventive concepts.

FIG. 16 is a table showing threshold voltages of ground selection transistors in the semiconductor device illustrated in FIG. 14.

FIG. 17 is a plan view illustrating a portion of a memory cell array of a semiconductor device according to an embodiment of inventive concepts.

FIG. 18 is a cross-sectional view of a semiconductor device according to an embodiment of inventive concepts.

FIG. 19 is a circuit diagram illustrating a cell array of a semiconductor device according to embodiments of inventive concepts, and illustrates a voltage condition during a read operation.

FIG. 20 is a table showing threshold voltages of ground selection transistors in the semiconductor device illustrated in FIG. 19.

FIG. 21 is a circuit diagram illustrating a cell array of a semiconductor device according to embodiments of inventive concepts, and illustrates voltage conditions during a read operation.

FIG. 22 is a table showing threshold voltages of ground selection transistors in the semiconductor device illustrated in FIG. 21.

FIG. 23 is a cross-sectional view of a semiconductor device according to an embodiment of inventive concepts.

### DETAILED DESCRIPTION

Hereinafter, a semiconductor device and an electronic system including the same according to embodiments of inventive concepts will be described in detail with reference to the drawings.

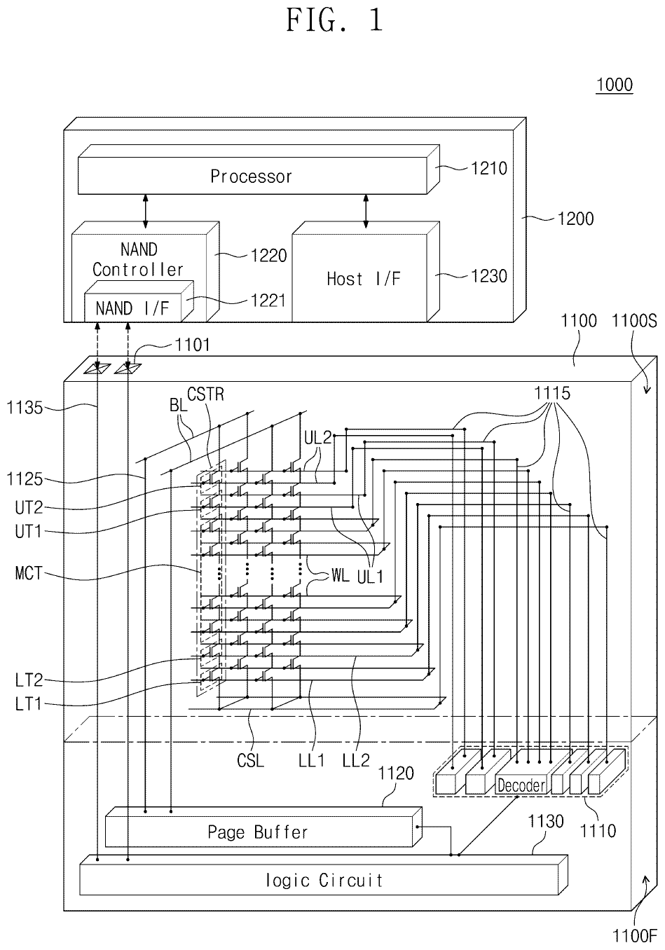

FIG. 1 is a diagram schematically illustrating an electronic system including a semiconductor device according to an embodiment of inventive concepts.

Referring to FIG. 1, an electronic system 1000 according to some embodiments of inventive concepts may include a semiconductor device 1100 and a controller 1200, which are electrically connected to each other. The electronic system 1000 may be or may include a storage device including one or more semiconductor devices 1100 and/or an electronic device including the storage device. For example, the electronic system 1000 may be or may include at least one of a solid state drive (SSD) device, a universal serial bus (USB), a computing system, a medical system, or a communication system, in which at least one semiconductor device 1100 is provided.

The semiconductor memory device 1100 may be a nonvolatile memory device, and for example may be a NAND flash memory device. The semiconductor memory device 1100 may include a first structure 1100F and a second structure 1100S on the first structure 1100F. According to some embodiments, the first structure 1100F alternatively may be disposed at a side of the second structure 1100S.

The first structure 1100F may be a peripheral circuit structure, which includes a decoder circuit 1110, a page buffer 1120, and a logic circuit 1130. The second structure 1100S may be a memory cell structure, which includes bit lines BL, a common source line CSL, word lines WL, first and second gate upper lines UL1 and UL2, first and second gate lower lines LL1 and LL2, and memory cell strings CSTR between the bit lines BL and the common source line CSL.

In the second structure 1100S, each of the memory cell strings CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. The number of the lower transistors LT1 and LT2 and the number of the upper transistors UT1 and UT2 may be variously changed, according to various embodiments.

In embodiments, the upper transistors UT1 and UT2 may include at least one string selection transistor, and the lower transistors LT1 and LT2 may include at least one ground selection transistor. The gate lower lines LL1 and LL2 may be respectively used as gate electrodes of the lower transistors LT1 and LT2. The word lines WL may be respectively used as gate electrodes of the memory cell transistors MCT, and the gate upper lines UL1 and UL2 may be respectively used as gate electrodes of the upper transistors UT1 and UT2.

The memory cells MCT of each memory cell string CSTR may be controlled by the back gate line.

The common source line CSL, the first and second gate lower lines LL1 and LL2, the word lines WL, and the first and second gate upper lines UL1 and UL2 may be electrically connected to the decoder circuit 1110 through first connection lines 1115, which are extended from the first structure 1100F into the second structure 1100S. The bit lines BL may be electrically connected to the page buffer 1120 through second connection lines 1125, which are extended from the first structure 1100F into the second structure 1100S.

In the first structure 1100F, the decoder circuit 1110 and the page buffer 1120 may be configured to control a control operation, which is performed on at least one of the memory cell transistors MCT by a selection memory cell transistor. The decoder circuit 1110 and the page buffer 1120 may be controlled by the logic circuit 1130. The semiconductor device 1100 may communicate with the controller 1200 through an input/output pad 1101, which is electrically connected to the logic circuit 1130. The input/output pad 1101 may be electrically connected to the logic circuit 1130 through an input/output connection line 1135, which is provided in the first structure 1100F and is extended into the second structure 1100S.

Although not illustrated in the drawing, the first structure 1100F may include a voltage generator (not shown). The voltage generator may generate at least one of a program voltage, a read voltage, a pass voltage, a verification voltage, and so forth, which are used or needed to operate the memory cell strings CSTR. Here, the program voltage may be a relatively high voltage (e.g., 20V to 40V), compared with any of the read voltage, the pass voltage, and the verification voltage.

In embodiments, the first structure 1100F may include high-voltage transistors (e.g. transistors having a high threshold voltage) and low-voltage transistors (e.g. transistors having a lower threshold voltage). The decoder circuit 1110 may include pass transistors which are connected to the word lines WL of the memory cell strings CSTR. The pass transistors may include high-voltage transistors which can stand or operate under a high voltage (e.g., the program voltage) applied to the word lines WL during a programming operation). The page buffer 1120 may also high-voltage transistors which can stand the high voltage.

The controller 1200 may include a processor 1210, a NAND controller 1220, and a host interface 1230. In some embodiments, the electronic system 1000 may include a plurality of semiconductor devices 1100, and in this case, the controller 1200 may control the semiconductor devices 1100.

The processor 1210 may control overall operations the electronic system 1000 including the controller 1200. The processor 1210 may be operated based on a specific firmware and/or software and/or hardware and may control the NAND controller 1220 to access the semiconductor device 1100. The NAND controller 1220 may include a NAND interface 1221, which is used to communicate with the semiconductor device 1100. The NAND interface 1221 may be used to transmit and receive control commands to control the semiconductor device 1100, and/or data to be written in or read from the memory cell transistors MCT of the semiconductor device 1100, and/or so forth. The host interface 1230 may be configured to allow for communication between the electronic system 1000 and an external host. When a control command is received from an external host through the host interface 1230, the processor 1210 may be control the semiconductor device 1100 in response to the control command.

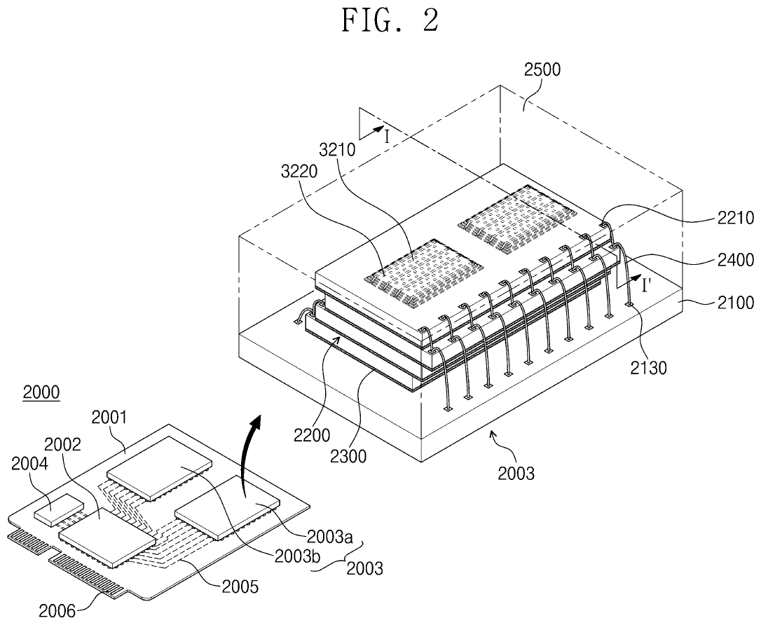

FIG. 2 is a perspective view schematically illustrating an electronic system including a semiconductor device according to an embodiment of inventive concepts.

Referring to FIG. 2, an electronic system 2000 according to some embodiments of inventive concepts may include a main board 2001 and a controller 2002, at least one semiconductor package 2003, and a DRAM 2004, which are mounted on the main board 2001. The semiconductor package 2003 and the DRAM 2004 may be connected to the controller 2002 and to each other by interconnection patterns 2005, which are formed in the main board 2001.

The main board 2001 may include a connector 2006, which includes a plurality of pins coupled to an external host. In the connector 2006, the number and/or the arrangement of the pins may depend on a communication interface between the electronic system 2000 and the external host. In some embodiments, the electronic system 2000 may communicate with the external host, in accordance with one of interfaces, such as universal serial bus (USB), peripheral component interconnect express (PCI-Express), serial advanced technology attachment (SATA), universal flash storage (UFS) M-Phy, or the like. In some embodiments, the electronic system 2000 may be driven by a power, which is supplied from the external host through the connector 2006. The electronic system 2000 may further include a Power management integrated circuit (PMIC) distributing a power (not illustrated), which is supplied from the external host, to the controller 2002 and the semiconductor package 2003.

The controller 2002 may be configured to control a writing or reading operation on the semiconductor package 2003 and to improve an operation speed of the electronic system 2000.

The DRAM 2004 may be or may include a buffer memory, which relieves or helps to relieve technical difficulties caused by a difference in speed between the semiconductor package 2003, which serves as a data storage device, and an external host. In some embodiments, the DRAM 2004 in the electronic system 2000 may serve as a cache memory and may provide a storage space to temporarily store data during a control operation on the semiconductor package 2003. When the electronic system 2000 includes the DRAM 2004, the controller 2002 may further include a DRAM controller to control the DRAM 2004, in addition to a NAND controller to controlling the semiconductor package 2003; alternatively there may be one controller to control the DRAM 2004 and the semiconductor package 2003.

The semiconductor package 2003 may include first and second semiconductor packages 2003a and 2003b, which are spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, the semiconductor chips 2200 on the package substrate 2100, adhesive layers 2300 disposed on respective bottom surfaces of the semiconductor chips 2200, a connection structure 2400 electrically connecting the semiconductor chips 2200 to the package substrate 2100, and a molding layer 2500 disposed on the package substrate 2100 to cover the semiconductor chips 2200 and the connection structure 2400.

The package substrate 2100 may be or may include a printed circuit board including package upper pads 2130. Each of the semiconductor chips 2200 may include an input/output pad 2210. The input/output pad 2210 may correspond to the input/output pad 1101 of FIG. 1. Each of the semiconductor chips 2200 may include gate stacks 3210 and vertical structures 3220. Each of the semiconductor chips 2200 may include a semiconductor device, which will be described below, according to some embodiments of inventive concepts.

In some embodiments, the connection structure 2400 may be a bonding wire electrically connecting the input/output pad 2210 to the package upper pads 2130. Thus, in each of the first and second semiconductor packages 2003a and 2003b, the semiconductor chips 2200 may be electrically connected to each other in a bonding wire manner and may be electrically connected to the package upper pads 2130 of the package substrate 2100. Alternatively or additionally in some example embodiments, the semiconductor chips 2200 in each of the first and second semiconductor packages 2003a and 2003b may be electrically connected to each other by a connection structure including through silicon vias (TSVs), not by the connection structure 2400 provided in the form of bonding wires.

In some embodiments, the controller 2002 and the semiconductor chips 2200 may be included in a single package. In some embodiments, the controller 2002 and the semiconductor chips 2200 may be mounted on a separate interposer substrate, which is prepared regardless of the main board 2001, and may be connected to each other through interconnection lines, which are provided in the interposer substrate.

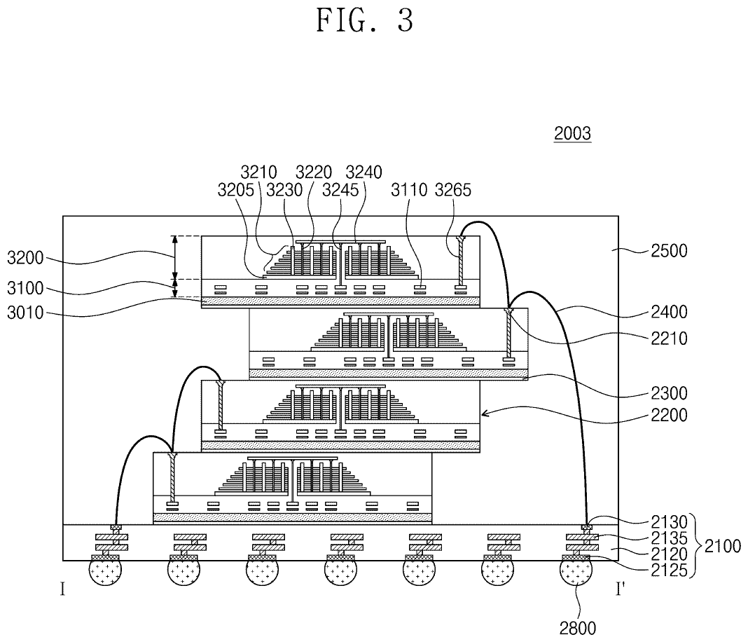

FIGS. 3 and 4 are cross-sectional views schematically illustrating semiconductor packages according to an embodiment of inventive concepts. FIGS. 3 and 4 are sectional views, which are taken along a line I-I′ of FIG. 1, and illustrate embodiments of the semiconductor package of FIG. 1.

Referring to FIG. 3, in the semiconductor package 2003, the package substrate 2100 may be or may include a printed circuit board. The package substrate 2100 may include a package substrate body portion 2120, the upper pads 2130 (e.g., of FIG. 1), which are disposed on a top surface of the package substrate body portion 2120, lower pads 2125, which are disposed on or exposed through a bottom surface of the package substrate body portion 2120, and internal lines 2135, which are provided in the package substrate body portion 2120 to electrically connect the upper pads 2130 to the lower pads 2125. The upper pads 2130 may be electrically connected to the connection structures 2400. The lower pads 2125 may be connected to the interconnection patterns 2005, which are provided in the main board 2001 of the electronic system 2000, through conductive connecting portions 2800, as shown in FIG. 2.

Each of the semiconductor chips 2200 may include a semiconductor substrate 3010 and first and second structures 3100 and 3200, which are sequentially stacked on the semiconductor substrate 3010. The first structure 3100 may include a peripheral circuit region, in which peripheral lines 3110 are provided. The second structure 3200 may include a source structure 3205, a stacked structure 3210 on the source structure 3205, a vertical structures 3220 and separation structures 3230 penetrating the stacked structure 3210, bit lines 3240 electrically connected to the vertical structures 3220, and cell contact plugs 3235 electrically connected to the word lines WL (e.g., of FIG. 1) of the stacked structure 3210. Each of the first and second structures 3100 and 3200 and the semiconductor chips 2200 may further include separation structures to be described below.

Each of the semiconductor chips 2200 may include penetration lines 3245, which are electrically connected to the peripheral lines 3110 of the first structure 3100 and are extended into the second structure 3200. The penetration line 3245 may be disposed outside the stacked structure 3210, and in some embodiments, the penetration line 3245 may be provided to further penetrate the stacked structure 3210. Each of the semiconductor chips 2200 may further include the input/output pad 2210 (e.g., see FIG. 2), which are electrically connected to the peripheral lines 3110 of the first structure 3100.

Referring to FIG. 4, in a semiconductor package 2003A, each of semiconductor chips 2200 a may include a semiconductor substrate 4010, a first structure 4100 on the semiconductor substrate 4010, and a second structure 4200, which is provided on the first structure 4100 and is bonded with the first structure 4100 in a wafer bonding manner.

The first structure 4100 may include a peripheral circuit region, in which a peripheral line 4110 and first junction structures 4150 are provided. The second structure 4200 may include a source structure 4205, a stacked structure 4210 between the source structure 4205 and the first structure 4100, vertical structures 4220 and a separation structure 4230 penetrating the stacked structure 4210, and second junction structures 4250, which are respectively and electrically connected to the vertical structures 4220 and the word lines WL (e.g., of FIG. 1) of the stacked structure 4210. For example, the second junction structures 4250 may be electrically and respectively connected to the vertical structures 4220 and the word lines WL (e.g., of FIG. 1) through bit lines 4240, which are electrically connected to the vertical structures 4220, and cell contact plugs 4235, which are electrically connected to the word lines WL (e.g., of FIG. 1). The first junction structures 4150 of the first structure 4100 may be in contact with and coupled to the second junction structures 4250 of the second structure 4200. The coupled portions of the first junction structures 4150 and the second junction structures 4250 may be formed of or include, for example, copper (Cu); however, example embodiments are not limited thereto.

Each of the first and second structures 4100 and 4200 and the semiconductor chips 2200 a may further include a source structure, as will be described below with reference to some embodiments. Each of the semiconductor chips 2200 a may further include the input/output pads 2210 (e.g., of FIG. 2), which are electrically connected to the peripheral lines 4110 of the first structure 4100.

The semiconductor chips 2200 of FIG. 3 and the semiconductor chips 2200a of FIG. 4 may be electrically connected to each other by the connection structures 2400, which are provided in the form of bonding wires. Alternatively, in some embodiments, semiconductor chips, which are provided in the same semiconductor package as the semiconductor chips 2200 of FIG. 3 and the semiconductor chips 2200a of FIG. 4, may be electrically connected to each other by a connection structure including through silicon vias (TSVs).

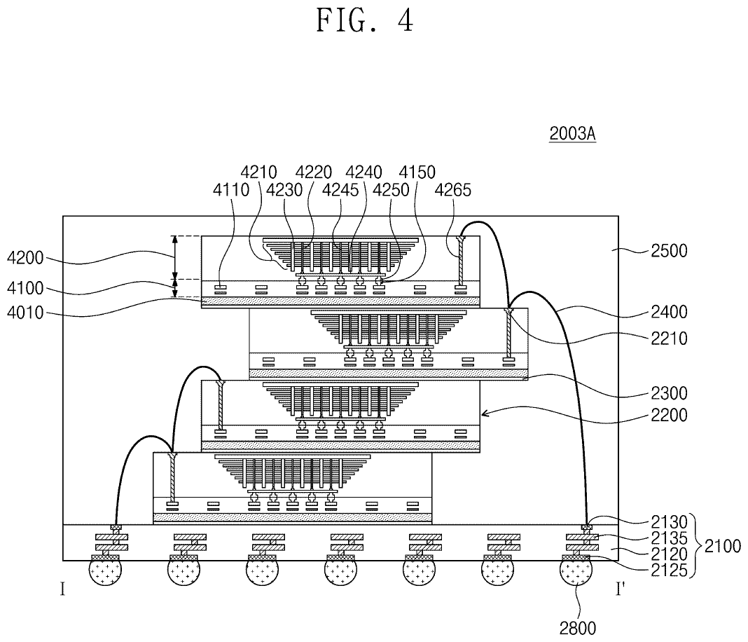

FIG. 5 is a schematic block diagram illustrating a memory cell array of a semiconductor device according to embodiments of inventive concepts.

Referring to FIG. 5, a semiconductor device according to embodiments may include a memory cell array and a peripheral circuit that controls the memory cell array. The peripheral circuit may include a decoder 1110 (refer to FIG. 1), a page buffer 1120 (refer to FIG. 1), and a logic circuit 1130 (refer to FIG. 1).

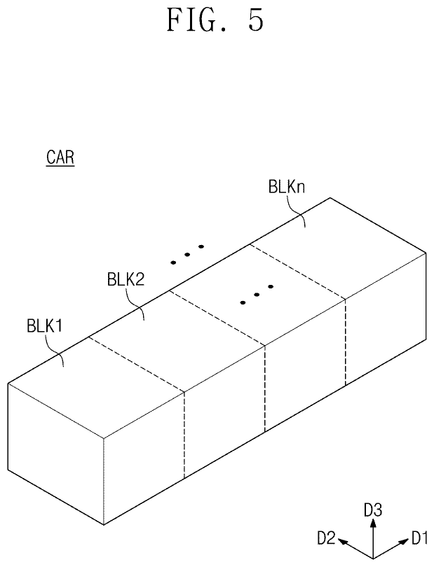

The memory cell array may include a plurality of memory blocks BLK1, BLK2, . . . , BLKn, where ‘n’ is a positive integer. Each of the memory blocks BLK1, BLK2, . . . , BLKn may include a stacked structure including conductive patterns stacked in a third direction D3 on a plane defined by first and second directions D1 and D2. The stacked structure may be coupled to a plurality of vertical structures (vertical pillars) to constitute three-dimensionally arranged memory cells. In addition, each of the memory blocks BLK1, BLK2, . . . , BLKn may include bit lines that are electrically connected to the memory cells. The memory blocks BLK1, BLK2, . . . , BLKn will be described in detail with reference to FIG. 6.

FIG. 6 is a circuit diagram illustrating a memory cell array of a semiconductor device according to embodiments of inventive concepts.

Referring to FIG. 6, the memory cell array may include first and second memory blocks BLK1 and BLK2. Each of the first and second memory blocks BLK1 and BLK2 may include a plurality of pages, and each of the pages may include a plurality of memory cells MC. For example, each of the memory blocks BLK1 and BLK2 may be a unit of erasing, and a page may be a unit of writing and reading. Each memory cell MC may store one or more bits. In detail, each memory cell MC is a single level cell (SLC), multi-level cell (MLC), triple level cell (TLC), or quadruple level cell (QLC).

The first and second memory blocks BLK1 and BLK2 each have a plurality of word lines WL, a plurality of string selection lines SSL0 to SSL5, a plurality of ground selection lines GSL0 to GSL3, and a plurality of bit lines BL1, BL2, and BL3. In addition, the first and second memory blocks BLK1 and BLK2 each have a plurality of cell strings CS1, CS2, CS3, CS4, CS5, and CS6 arranged in first and second directions D1 and D2 that intersect each other. The cell strings CS1 to CS6 may be connected to the bit lines BL1 to BL3 in parallel, respectively. The two-dimensionally arranged cell strings CS1 to CS6 may be commonly connected to the common source line CSL.

Each of the cell strings CS1 to CS6 may include a plurality of memory cells MC connected in series in a third direction D3 perpendicular to the first and second directions D1 and D2. In addition, each of the cell strings CS1 to CS6 may include a string selection transistor SST connected between the corresponding bit lines BL1, BL2, and BL3 and the memory cell MC, and a plurality of ground selection transistors GST0, GST1, GST2, and GST3 connected in series between the common source line CSL and the memory cell MC.

According to embodiments, the number of ground selection transistors GST0, GST1, GST2, and GST3 connected in series in each cell string CS1 to CS6 may be variously changed depending on the number of cell strings CS1 to CS6 connected in parallel to one bit line BL1, BL2, and BL3, that is, the number of string selection lines SSL0 to SSL5.

As an example, the bit lines BL1 to BL3 may include first, second, and third bit lines BL1, BL2, and BL3, and the cell strings CS1 to CS6 may include first to sixth cell strings CS1 to CS6 connected to each bit line BL1, BL2, and BL3. Inventive concepts are not limited thereto, and the number of cell strings connected to each bit line may be variously changed.

Each of the first and second memory blocks BLK1 and BLK2 may include six first to sixth string selection lines SSL0 to SSL5 that are electrically separated from each other. Each of the first to sixth string selection lines SSL0 to SSL5 may be commonly connected to gate electrodes of the string selection transistors SST arranged in the first direction D1.

The memory cells MC may be controlled by a plurality of word lines WL0-WLn, respectively. In each of the first and second memory blocks BLK1 and BLK2, gate electrodes of the memory cells MC positioned at the same level from the common source line CSL may be commonly connected to one of the word lines WL0 to WLn. Additionally, each of the memory cells MC may include a data storage element. That is, in each of the first and second memory blocks BLK1 and BLK2, memory cells MC positioned at the same height among the memory cells MC of the first to sixth cell strings CS1 to CS6 may share the same word line (one of WL0 to WLn).

In embodiments, each of the first to sixth cell strings CS1 to CS6 may include 2, 3, 4, 5, or 6 or more ground selection transistors. Additionally, in each cell string CS1 to CS6, a plurality of ground selection transistors GST0, GST1, GST2, and GST3 may have different threshold voltages.

In each of the first and second memory blocks BLK1 and BLK2, the string selection transistors SST of the first to sixth cell strings CS1 to CS6 may be controlled by the first to sixth string selection lines SSL0 to SSL5. That is, the string selection transistors SST of the first to sixth cell strings CS1 to CS6 connected to each bit line BL1 to BL3 may be electrically separated from each other.

In each of the first and second memory blocks BLK1 and BLK2, memory cells MC positioned at the same height among the memory cells MC of the first to sixth cell strings CS1 to CS6 may share the same word line (one of WL0 to WLn).

Among the ground selection transistors GST0 to GST3, the ground selection transistors GST0, GST1, GST2, or GST3 positioned at the same level may be connected to the same ground selection line GSL0, GSL1, GSL2, or GSL3.

For example, in each of the first and second memory blocks BLK1 and BLK2, the first ground selection transistors GST0 of the first to sixth cell strings CS1 to CS6 may be commonly connected to the first ground selection line GSL0, the second ground selection transistors GST1 may be commonly connected to the second ground selection line GSL1, the third ground selection transistors GST2 may be commonly connected to the third ground selection line GSL2, and the fourth ground selection transistors GST3 may be connected to the fourth ground selection line GSL3.

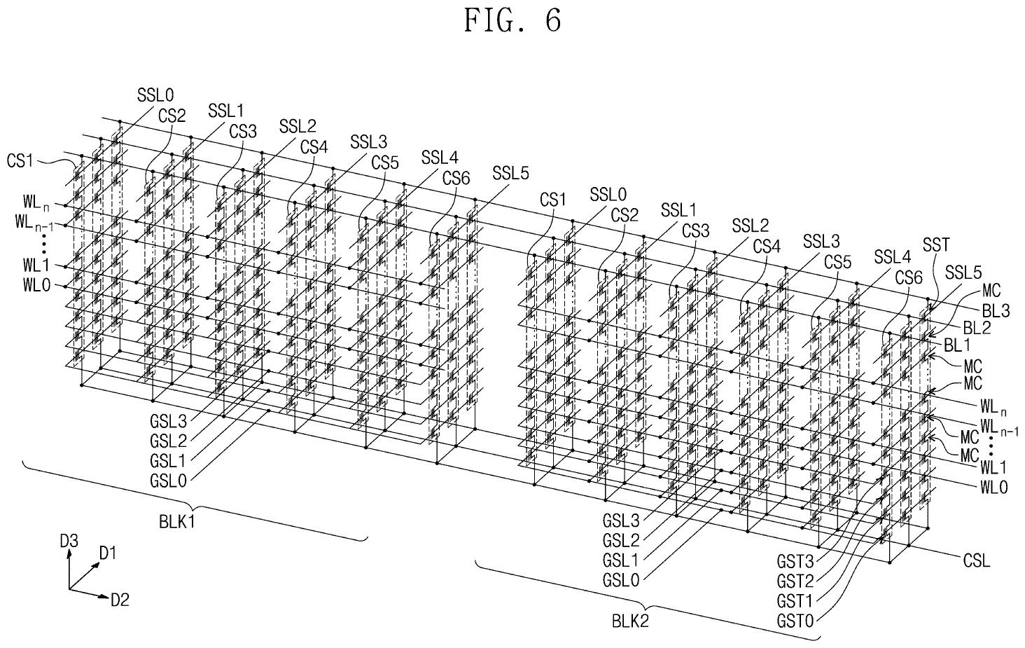

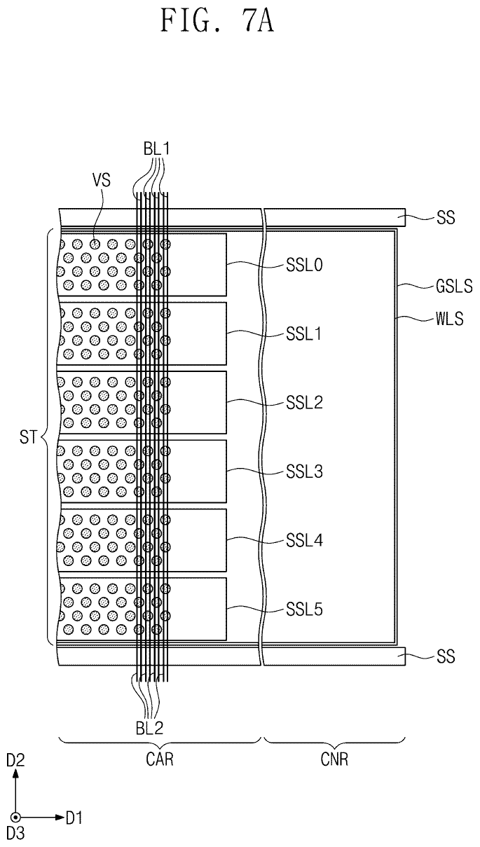

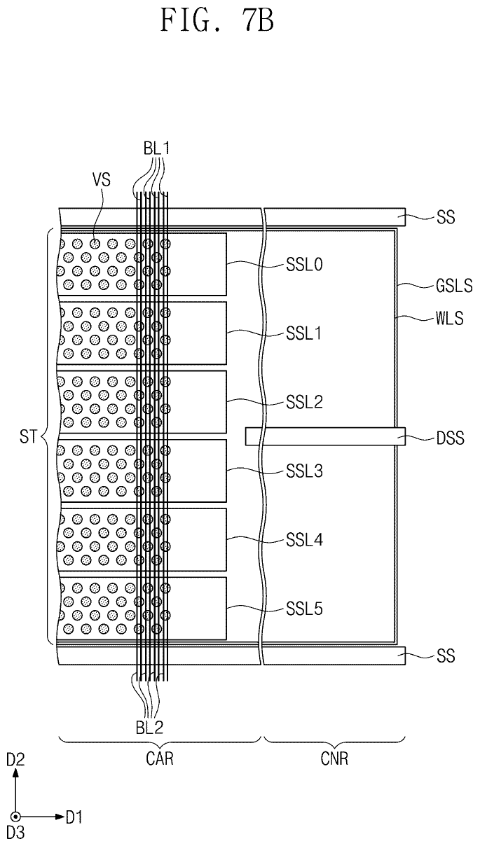

FIGS. 7A and 7B are plan views illustrating a portion of a memory cell array of a semiconductor device according to an embodiment of inventive concepts. FIG. 8A is a cross-sectional view of a semiconductor device according to an embodiment of inventive concepts. FIG. 8B is an enlarged view of a portion of a semiconductor device according to an embodiment of inventive concepts.

Referring to FIGS. 7A, 7B, and 8A, a substrate 100 may include a cell array region CAR and a connection region CNR. The connection region CNR may be adjacent to the cell array region CAR in a first direction D1 parallel to an upper surface of the substrate 100.

The substrate 100 may include at least one of, for example, silicon (Si), germanium (Ge), silicon germanium (SiGe), gallium arsenide (GaAs), indium gallium arsenide (InGaAs), aluminum gallium arsenide (AlGaAs), or a mixture thereof. The substrate 100 may include a semiconductor doped with impurities and/or an intrinsic semiconductor that is not doped with impurities. The substrate 100 may have a crystal structure including at least one selected from single crystal, amorphous, and polycrystalline. As another example, the substrate 100 may be formed of an insulating material such as silicon oxide.

Separation structures SS may extend parallel to each other in the first direction D1 from the cell array region CAR to the connection region CNR on the substrate 100. The separation structures SS may be spaced apart from each other in a second direction D2. The first direction D1 and the second direction D2 may be parallel to the upper surface of the substrate 100.

Each of the separation structures SS may have a single-layer or multi-layer structure. The separation structures SS may include an insulating layer covering both walls of a stacked structure ST. The separation structures SS may include at least one of silicon oxide, silicon nitride, or polysilicon.

A width of a lower portion of the separation structures SS may be smaller than a width of the upper portion thereof. Upper surfaces of the separation structures SS may be positioned at a higher level than upper surfaces of vertical structures VS. The upper surfaces of the separation structures SS may be positioned at substantially the same level as an upper surface of an upper insulating layer 110.

Referring to FIG. 7B, at least one dummy separation structure DSS may penetrate the stacked structure ST in the connection region CNR. In the first direction D1, a length of the dummy separation structure DSS may be smaller than a length of the separation structures SS. The dummy separation structure DSS may be spaced apart from string selection lines SSL0 to SSL5. Although one dummy separation structure DSS is illustrated in the drawing, inventive concepts are not limited thereto, and a plurality of dummy separation structures DSS may be provided in the connection region CNR.

According to embodiments, the stacked structure ST may be disposed between adjacent separation structures SS. The stacked structure ST may extend from the cell array region CAR to the connection region CNR in the first direction D1. The stacked structure ST may have a staircase structure on the connection region CNR. Alternatively, the stacked structure ST may have a uniform thickness in the cell array region CAR and connection region CNR.

The stacked structure ST may include a ground selection structure GSLS, a word line structure WLS, and a string selection structure SSL0 to SSL5 sequentially stacked on the substrate 100.

The ground selection structure GSLS may include a plurality of ground selection lines GSL0 to GSL3 vertically stacked on the substrate 100 with an interlayer insulating layer ILD interposed therebetween. Additionally, the ground selection structure GSLS may include common ground selection lines CGSLu and CGSLd between the substrate 100 and the first ground selection line GSL0.

The word line structure WLS may include a plurality of word lines WL0 to WLn (where ‘n’ is a positive integer) vertically stacked on the ground selection structure GSLS with an interlayer insulating layer ILD interposed therebetween. The string selection structure may include a plurality of string selection lines SSL0 to SSL5 that are horizontally spaced apart from each other on the word line structure WLS. The string selection lines SSL0 to SSL5 may be spaced apart from each other in the second direction D2 by separation insulating patterns SIP disposed on the word line structure WLS.

As an example, the stacked structure ST may include first to fourth ground selection lines GSL0 to GSL3 that are vertically stacked, and first to sixth string selection lines SSL0 to SSL5 that are horizontally spaced apart from each other. The first to sixth string selection lines SSL0 to SSL5 may overlap the first to fourth ground selection lines GSL0 to GSL3, respectively, when viewed in a plan view. In the second direction D2, a width of each of the word lines WL0 to WLn may be greater than the sum of widths of the string selection lines SSL0 to SSL5. In the second direction D2, width of each of the ground selection lines GSL0 to GSL3 may be greater than the sum of widths of the string selection lines SSL0 to SSL5.

Each of the first to fourth ground selection lines GSL0 to GSL3 may not be physically separated from the separation structures SS and may be a single layer in a form of a line.

In embodiments, upper and lower common ground selection lines CGSLu and CGSLd, ground selection lines GSL0 to GSL3, word lines WL0 to WLn, and string selection lines SSL0 to SSL5 may include at least one selected from, for example, a doped semiconductor (e.g., doped silicon, etc.), a metal (e.g., tungsten, copper, aluminum, etc.), a conductive metal nitride (e.g., titanium nitride, tantalum nitride, etc.), or a transition metal (e.g., titanium, tantalum, etc.). The interlayer dielectric layers ILD may include a silicon oxide layer and/or a low dielectric layer.

A plurality of vertical structures VS may penetrate the stacked structure ST in the cell array region CAR. The vertical structures VS may be arranged in one direction or in a zigzag form, when viewed in a plan view. As an example, the vertical structures VS arranged in the first direction D1 may form one column, and a plurality of columns may be arranged to alternate with each other in the second direction D2.

Each of the vertical structures VS may have a maximum width at an upper surface of the uppermost insulating layer ILD. Each of the vertical structures VS may have a minimum width at a bottom layer thereof, and the minimum width may be smaller than the maximum width. Alternatively, each of the vertical structures VS may have a width at the upper layer thereof and a width at the bottom layer thereof that are substantially the same. A distance between adjacent vertical structures VS may be smaller than the maximum width of each of the vertical structures VS.

In detail, referring to FIG. 8B, each of the vertical structures VS may include a vertical semiconductor pattern VP and a data storage pattern DSP surrounding a sidewall of the vertical semiconductor pattern VP, and a gap-fill insulating pattern VI inside vertical semiconductor pattern VP.

In detail, the vertical semiconductor pattern VP may have a pipe shape or a macaroni shape with a closed bottom. The vertical semiconductor pattern VP may have a U-shape, and an interior thereof may be filled with the gap-fill insulating pattern VI. A bit line conductive pad may be formed on an upper end of the vertical semiconductor pattern VP, and the bit line conductive pad may be formed of a semiconductor material undoped with impurities, a semiconductor material doped with impurities, or a conductive material.

The vertical semiconductor pattern VP may include a semiconductor material such as silicon (Si), germanium (Ge), or a mixture thereof. The vertical semiconductor pattern VP including a semiconductor material may be used as channels for memory cells constituting a cell string.

The data storage pattern DSP may extend in a third direction D3 to surround a sidewall of each vertical semiconductor pattern VP. The data storage pattern DSP may be in a form of a pipe with open top and bottom or a macaroni shape. The data storage pattern DSP may be formed of one thin layer or multiple thin layers. In embodiments of inventive concepts, the data storage pattern DSP may be a data storage layer of a NAND flash memory device, and may include a tunnel insulating layer TIL, a charge storage layer CIL, and a blocking insulating layer BLK sequentially stacked on the sidewalls of the vertical semiconductor pattern VP. For example, the charge storage layer CIL may be a trap insulating layer, a floating gate electrode, or an insulating layer including conductive nano dots. In detail, the charge storage layer CIL may include at least one of a silicon nitride layer, a silicon oxynitride layer, a silicon-rich nitride layer (Si-rich nitride), nanocrystalline silicon (nanocrystalline Si), and a laminated trap layer. The tunnel insulating layer TIL may be one of materials having a larger band gap than the charge storage layer CIL, and the blocking insulating layer BLK may be a high-k dielectric layer such as an aluminum oxide layer or a hafnium oxide layer.

A horizontal insulating pattern HP may be provided between one side walls of the conductive patterns GSL and WL and the data storage pattern DSP. The horizontal insulating pattern HP may extend on one sidewalls of the conductive patterns GSL0, GSL1, GSL2, DWL, CGSLu, and CGSLd to upper and lower surfaces thereof. The horizontal insulating pattern HP may include, for example, a silicon oxide layer and/or a high-k dielectric layer.

Again, referring to FIGS. 7A and 8A, bit lines BL1 and BL2 may cross the stacked structure ST on the cell array region CAR. The bit lines BL1 and BL2 are spaced apart from each other in the first direction D1 on the stacked structure ST and may extend in the second direction D2.

In detail, the bit lines BL1 and BL2 may be disposed on the upper insulating layer 110. The bit lines BL1 and BL2 may be arranged with a constant pitch in the first direction D1.

Each of the two bit lines BL1 and BL2 may be disposed on the vertical structures VS arranged in a row in the second direction D2. That is, a pair of bit lines BL1 and BL2 may be disposed on an upper portion of each of the vertical structures VS. A line width of each of the bit lines BL1 and BL2 may be less than half diameter of each of the vertical structures VS.

The bit lines BL1 and BL2 may include first and second bit lines BL1 and BL2 disposed on each vertical structure VS, and the first and second bit lines BL1 and BL2 may be repeatedly arranged in the first direction D1.

Each of the first bit lines BL1 may be electrically connected to the vertical structures VS of the odd-numbered columns, and each of the second bit lines BL1 may be electrically connected to the vertical structures VS of the even-numbered columns.

The common source line CSL (in FIG. 6) may be an impurity region (e.g., an n-type impurity (e.g., arsenic (As) or phosphorus (P) region)) provided in the substrate 100. In this case, a common source line may extend in the first direction D1 under the separation structures SS.

Alternatively, as a common source line CSL (in FIG. 6), a common source structure may be provided between the substrate 100 and the stacked structure ST.

In detail, referring to FIG. 8B, the source structure CST may include a source pattern SC and a support pattern SP on the source pattern SC. The source structure CST may be parallel to the upper surface of the substrate 100 and may extend in the first direction D1 parallel to the stacked structure ST.

The source pattern SC may be in contact with a portion of the sidewall of the vertical semiconductor pattern VP of each vertical structure VS. Upper and lower surfaces of the support pattern SP may be in contact with the data storage pattern DSP. The source pattern SC may include a sidewall portion disposed between a sidewall of the vertical semiconductor pattern VP and the support pattern SP, and between the sidewall of the vertical semiconductor pattern VP and the substrate 100.

The source pattern SC may be formed of a semiconductor material doped with dopants having a first conductivity type (e.g., phosphorus (P) or arsenic (As)). As an example, the source conductive pattern may be formed of a polysilicon layer doped with n-type dopants.

The support pattern SP may cover an upper surface of the source pattern SC, and a portion of the support pattern SP may penetrate the source pattern SC and may be in contact with the substrate 100. The support pattern SP may include a semiconductor doped with dopants having a first conductivity type (e.g., n-type) and/or an intrinsic semiconductor that is not doped with impurities. A concentration of n-type dopants in the support pattern SP may be lower than that in the source pattern SC.

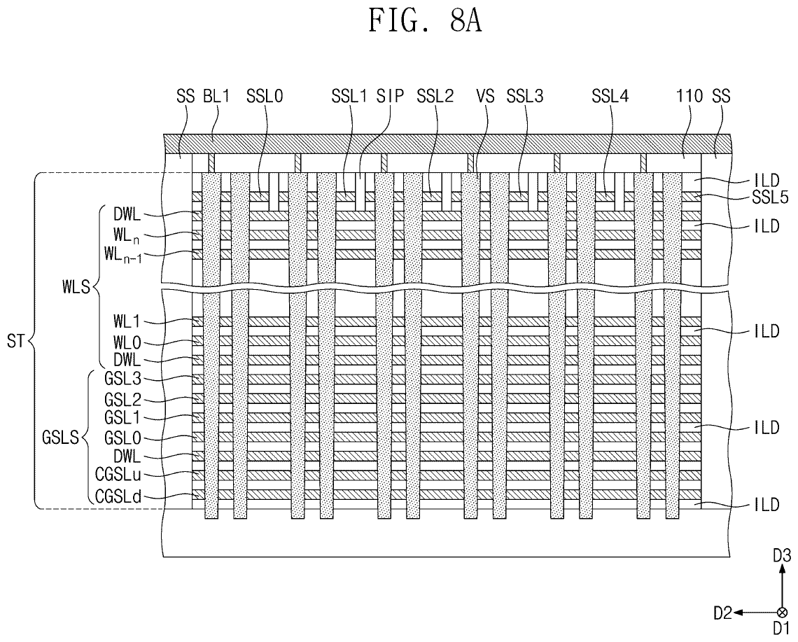

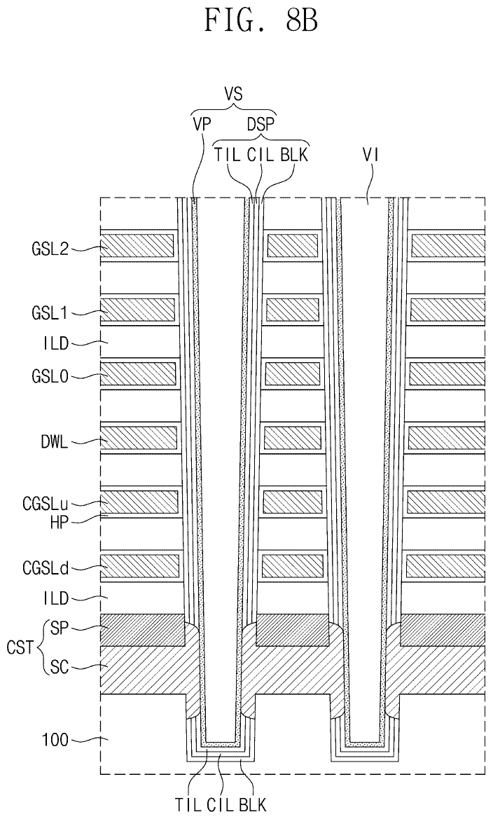

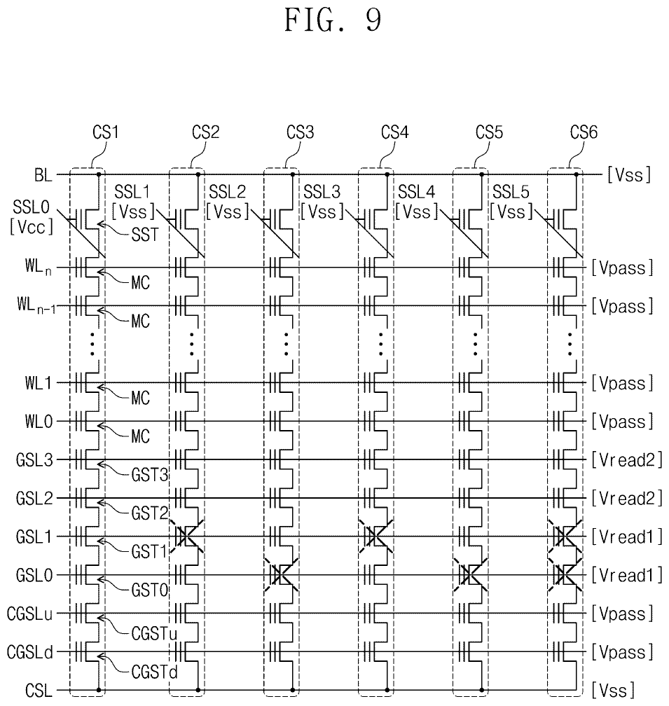

FIG. 9 is a circuit diagram illustrating a cell array of a semiconductor device according to embodiments of inventive concepts, and illustrates a voltage condition during a read operation. FIG. 10 is a diagram illustrating a threshold voltage distribution of ground selection transistors in a memory cell array of a semiconductor device according to an embodiment of inventive concepts. FIG. 11 is a table showing threshold voltages of ground selection transistors in the semiconductor device illustrated in FIG. 9.

Referring to FIG. 9, in each memory block BLK1 or BLK2 (in FIG. 6), each bit line BL may include first to sixth cell strings CS1 to CS6.

Each of the first to sixth cell strings CS1 to CS6 may include a string selection transistor SST, a plurality of memory cells MC connected in series, a plurality of ground selection transistors GST0, GST1, GST2, and GST3 connected in series, and common ground selection transistors CGSTu and CGSTd.

The string selection transistors SST of the first to sixth cell strings CS1 to CS6 may be controlled by the first to sixth string selection lines SSL0 to SSL5, respectively.

Each of the first to sixth cell strings CS1 to CS6 may include first, second, third, and fourth ground selection transistors GST0, GST1, GST2, and GST3. In the first to sixth cell strings CS1 to CS6, the first ground selection transistors GST0 positioned at the same level may be controlled by one first ground selection line GSL0. The second ground selection transistors GST1 positioned at the same level may be controlled by one second ground selection line GSL1. The third ground selection transistors GST2 positioned at the same level may be controlled by one third ground selection line GSL2. The fourth ground selection transistors GST3 positioned at the same level may be controlled by one fourth ground selection line GSL3.

The memory cells MC of the first to sixth cell strings CS1 to CS6 may be controlled by word lines WL0 to WLn. The common ground selection transistors CGSTu and CGSTd of the first to sixth cell strings CS1 to CS6 may be controlled by upper and lower common ground selection lines CGSLu and CGSLd.

Referring to FIGS. 9 and 10, first, second, third, and fourth ground selection transistors GST0, GST1, GST2, and GST3 in each of the first to sixth cell strings CS1 to CS6 may have a first threshold voltage distribution Vth1 or a second threshold voltage distribution Vth2. According to embodiments, the first to fourth ground selection transistors GST0 to GST3 of each cell string may be programmed to have the first threshold voltage distribution Vth1 or the second threshold voltage distribution Vth2, as illustrated in FIG. 11. Here, the second threshold voltage distribution Vth2 may be at a higher level than the first threshold voltage distribution Vth1.

As an example, before the first to fourth ground selection transistors GST0 to GST3 are programmed, the first to fourth ground selection transistors GST0 to GST connected to the first to fourth ground selection lines GSL0 to GSL3 may have the first threshold voltage distribution Vth1, and then, in each cell string CS1 to CS6, a program voltage may be applied to a selected one of the first to fourth ground selection lines GSL0 to GSL3 and the first to fourth ground selection transistors GST0 to GST3 may be selectively programmed by applying a pass voltage to the others. The selected first to fourth ground selection transistors GST0 to GST3 may have the second threshold voltage distribution Vth2 at a higher level than the first threshold voltage distribution Vth1.

Referring to FIGS. 9, 10, and 11, in the first cell string CS1, the first and second ground selection transistors GST0 and GST1 may have the first threshold voltage distribution Vth1, and the third and fourth ground selection transistors GST2 and GST3 may have the second threshold voltage distribution Vth2.

In the second cell string CS2, the first and third ground selection transistors GST0 and GST2 may have the first threshold voltage distribution Vth1, and the second and fourth ground selection transistors GST1 and GST3 may have the second threshold voltage distribution Vth2.

In the third cell string CS3, the second and third ground selection transistors GST1 and GST2 may have the first threshold voltage distribution Vth1, and the first and fourth ground selection transistors GST0 and GST3 may have the second threshold voltage distribution Vth2.

In the fourth cell string CS4, the first and fourth ground selection transistors GST0 and GST3 may have the first threshold voltage distribution Vth1, and the second and third ground selection transistors GST1 and GST2 may have the second threshold voltage distribution Vth2.

In the fifth cell string CS5, the second and fourth ground selection transistors GST1 and GST3 may have the first threshold voltage distribution Vth1, and the first and third ground selection transistors GST0 and GST2 may have the second threshold voltage distribution Vth2.

In the sixth cell string CS6, the third and fourth ground selection transistors GST2 and GST3 may have the first threshold voltage distribution Vth1, and the first and second ground selection transistors GST0 and GST1 may have the second threshold voltage distribution Vth2.

Referring to FIG. 9, during a read operation, a ground voltage Vss (or 0V) may be applied to the selected bit line BL, and when the first cell string CS1 is selected, a power supply voltage Vcc may be applied to the selected first string selection line SSL0, and a ground voltage Vss (or 0V) may be applied to the unselected string selection lines SSL1 to SSL5.

When the first to fourth ground selection transistors GST0 to GST4 of the first to sixth cell strings CS1 to CS6 are programmed to have a threshold voltage distribution as illustrated in FIG. 11, during a read operation, a first read voltage Vread1 may be applied to the first and second ground selection lines GSL0 and GSL1, and a second read voltage Vread2 greater than the first read voltage Vread1 may be applied to the third and fourth ground selection lines GSL2 and GSL3. Under the voltage condition, all of the first to fourth ground selection transistors GST0 to GST3 of the first cell string CS1 may be turned on. The second ground selection transistors GST1 of the second, fourth, and sixth cell strings CS2, CS4, and CS6 may be turned off, and the first ground selection transistors GST0 of the third, fifth, and sixth cell strings CS3, CS5, and CS6 may be turned off.

A pass voltage Vpass may be applied to the word lines WL0 to WLn and the upper and lower common ground selection lines CGSLu and CGSLd. In this case, the pass voltage Vpass may be selected in a range that is larger than the threshold voltage of the memory cells and smaller than the program voltage Vpgm. When the pass voltage Vpass is applied to the word lines WL0 to WLn and the upper and lower common ground selection lines CGSLu and CGSLd, the memory cells MC and the upper and lower common ground transistors CGSTu and CGSTd may be turned on.

Accordingly, when the selected first cell string CS1 is electrically connected between the bit line BL and the common source line CSL, the unselected second, third, fourth, fifth, and sixth cells strings CS2, CS3, CS4, CS5, and CS6 may be electrically separated from the common source line CSL and bit line BL by the second, third, and fourth ground selection transistors GST1, GST2, and GST3.

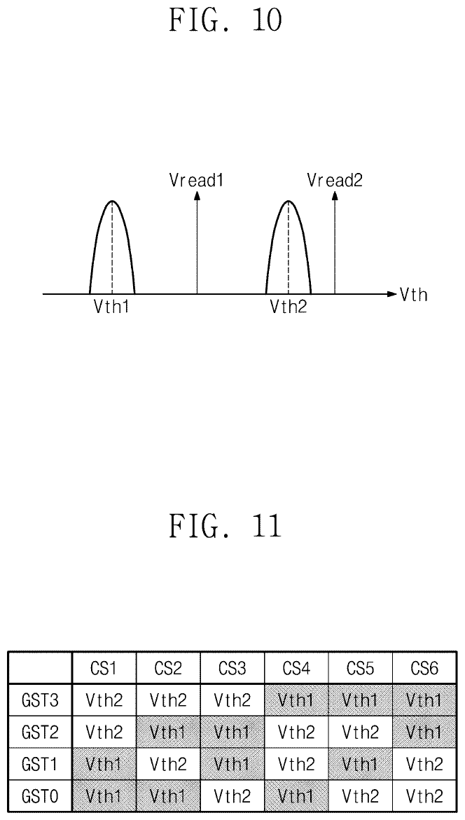

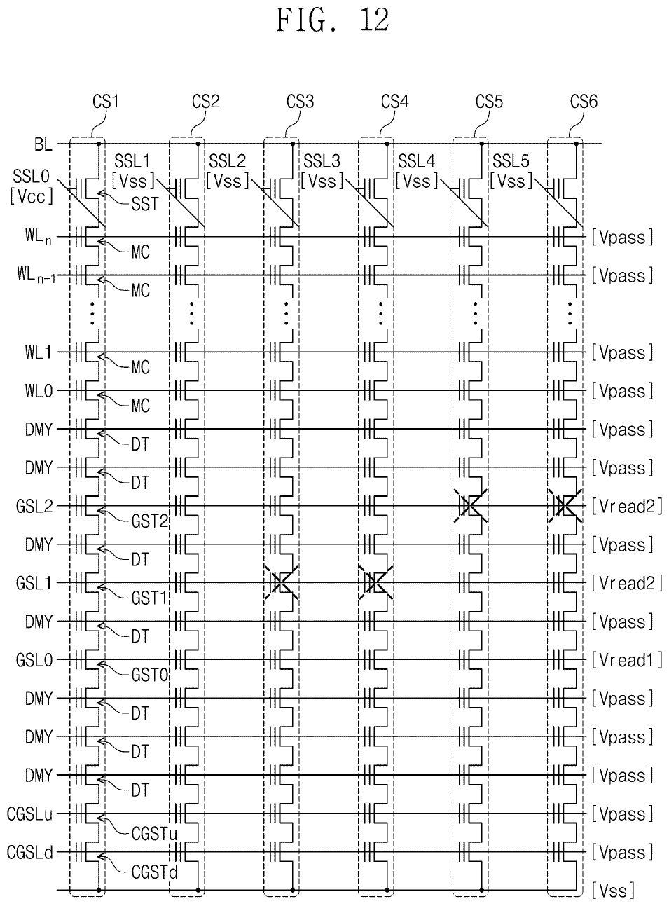

FIG. 12 is a circuit diagram illustrating a cell array of a semiconductor device according to embodiments of inventive concepts, and illustrates a voltage condition during a read operation. FIG. 13 is a table showing threshold voltages of ground selection transistors in the semiconductor device illustrated in FIG. 12.

Referring to FIGS. 12 and 13, in each memory block, first to sixth cell strings CS1 to CS6 may be connected to bit lines BL, respectively. Each of the first to sixth cell strings CS1 to CS6 may include a string selection transistor SST, a plurality of memory cells MC connected in series, a plurality of ground selection transistors GST0, GST1, and GST2 connected in series, and a common ground selection transistors CGSTu and CGSTd.

In detail, each of the first to sixth cell strings CS1 to CS6 may include first, second, and third ground selection transistors GST0, GST1, and GST2 and upper and lower common ground selection transistors CGSTu and CGSTd.

The first to third ground selection transistors GST0 to GST2 of the first to sixth cell strings CS1 to CS6 may be controlled by the first to third ground selection lines GSL0 to GSL2, respectively.

In addition, each of the first to sixth cell strings CS1 to CS6 may include dummy transistor DT between the memory cell MC and the ground selection transistor GST2, between the ground selection transistor GST0 and the common ground selection transistor CGST, and the ground selection transistors GST0, GST1, and GST2.

At least one dummy transistor DT may be connected between the upper common ground selection transistor CGSTu and the first ground selection transistor GST0. For example, three dummy transistors DT may be connected in series between the common ground selection transistor CGSTu and the first ground selection transistor GST0.

Dummy transistors DT may be connected between the first, second, and third ground selection transistors GST0, GST1, and GST2, respectively. At least one dummy transistor DT may be connected between the third ground selection transistor GST2 and the first word line WL0.

According to embodiments, as illustrated in FIG. 10, the first to third ground selection transistors GST0 to GST2 of each of the cell strings CS1 to CS6 may have a first or second threshold voltage distribution Vth1 or Vth2.

As an example, referring to FIG. 13, the first ground selection transistors GST0 of the first and second cell strings CS1 and CS2 may have the first threshold voltage distribution Vth1, and the second and third ground selection transistors GST1 and GST2 of the first and second cell strings CS1 and CS2 may have the second threshold voltage distribution Vth2 greater than the first threshold voltage distribution Vth1.

The second ground selection transistors GST1 of the third and fourth cell strings CS3 and CS4 may have the first threshold voltage distribution Vth1, and the first and third ground selection transistors GST0 and GST2 of the third and fourth cell strings CS3 and CS4 may have the second threshold voltage distribution Vth2 greater than the first threshold voltage distribution Vth1.

The third ground selection transistors GST2 of the fifth and sixth cell strings CS5 and CS6 may have the first threshold voltage distribution Vth1, and the first and second ground selection transistors GST0 and GST1 of the fifth and sixth cell strings CS5 and CS6 may have the second threshold voltage distribution Vth2 greater than the first threshold voltage distribution Vth1.

During a read operation of the semiconductor device according to the embodiment illustrated in FIGS. 12 and 13, a ground voltage Vss (or 0V) may be applied to a selected bit line BL, and when the first cell string CS1 is selected, a power supply voltage Vcc may be applied to a selected first string selection line SSL0, and a ground voltage Vss (or 0V) may be applied to the unselected string selection lines SSL1 to SSL5. Additionally, a first read voltage Vread1 may be applied to the first ground selection line GSL0, and a second read voltage Vread2 greater than the first read voltage Vread1 may be applied to the second and third ground selection lines GSL1 and GSL2.

Under the voltage condition, all of the first to third ground selection transistors GST0 to GST2 of the first cell string CS1 may be turned on. The second ground selection transistors GST1 of the third and fourth cell strings CS3 and CS4 may be turned off, and the third ground selection transistors GST2 of the fifth and sixth cell strings CS5 and CS6 may be turned off.

Furthermore, during a read operation, a pass voltage Vpass may be applied to the word lines WL0 to WLn, the upper and lower common ground selection lines CGSLu and CGSLd, and the dummy word lines DWL. In this case, the pass voltage Vpass may be selected in a range that is greater than the threshold voltage of the memory cells MC and less than the program voltage Vpgm. When the pass voltage Vpass is applied to the word lines WL0 to WLn and the upper and lower common ground selection lines CGSLu and CGSLd, the memory cells MC and the upper and lower common ground transistors CGSTu and CGSTd may be turned on.

Accordingly, when the first cell string CS1 in the selected bit line BL is electrically connected to the bit line BL and the common source line CSL, the unselected third, fourth, fifth, and sixth cell strings CS3, CS4, CS5, and CS6 may be electrically separated from the common source line CSL and the bit line BL by the second and third ground selection transistors GST2 and GST3. In the case of the second cell string CS2, the first to third ground selection transistors GST0 to GST2 may all be turned on, and the string selection transistor SST of the second cell string CS2 may be turned off, and thus the second cell string CS2 may be electrically separated from the selected bit line BL.

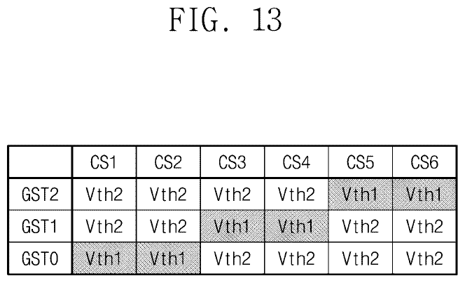

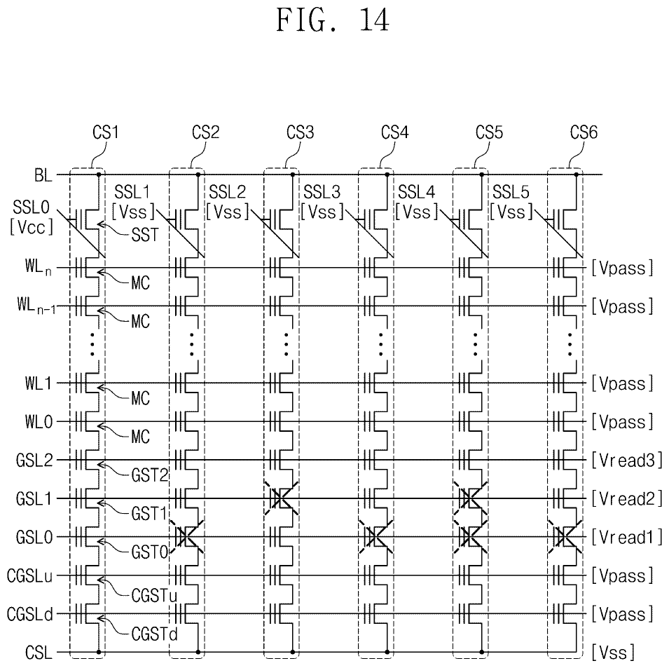

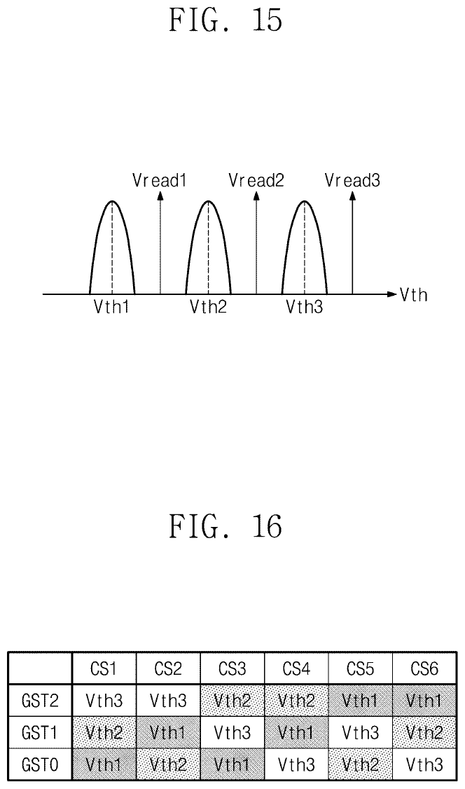

FIG. 14 is a circuit diagram illustrating a cell array of a semiconductor device according to embodiments of inventive concepts, and illustrates a voltage condition during a read operation. FIG. 15 is a diagram illustrating a threshold voltage distribution of ground selection transistors in a memory cell array of a semiconductor device according to an embodiment of inventive concepts. FIG. 16 is a table showing threshold voltages of ground selection transistors in the semiconductor device illustrated in FIG. 14.

Referring to FIGS. 14 and 15, first to sixth cell strings CS1 to CS6 may be connected to each bit line BL, and each of the first to sixth cell strings CS1 to CS6 may include first, second, and third ground selection transistors GST0, GST1, and GST2. Here, the first, second, and third ground selection transistors GST0, GST1, and GST2 may be programed to have a first threshold voltage distribution Vth1, a second threshold voltage distribution Vth2, or a third threshold voltage distribution Vth3. Here, the second threshold voltage distribution Vth2 may be at a higher level than the first threshold voltage distribution Vth1, and the third threshold voltage distribution Vth3 may be at a higher level than the second threshold voltage distribution Vth2. According to some embodiments, as described with reference to FIG. 12, each of the first to sixth cell strings CS1 to CS6 may include dummy transistors DT between the memory cell MC and the ground selection transistor GST2, between the ground selection transistor GST0 and the common ground selection transistor CGST, and between the ground selection transistors GST0, GST1, and GST2.

As an example, before the first to third ground selection transistors GST0 to GST2 are programmed, the first to third ground selection transistors GST0 to GST2 connected to the first to third ground selection lines GSL0 to GSL2 may have the first threshold voltage distribution Vth1, and then, in each of the cell strings CS1 to CS6, a program voltage may be applied to a selected one of the first to third ground selection lines GSL0 to GSL2 and a pass voltage may be applied to the others to selectively program the first to third ground selection transistors GST0 to GST2. Two program operations may be performed on some of the first to third ground selection transistors GST0 to GST2 to have the third threshold voltage distribution Vth3.

Referring to FIG. 15, the first ground selection transistors GST0 of the first and third cell strings CS1 and CS3 may have the first threshold voltage distribution Vth1, the first ground selection transistors GST0 of the second and fifth cell strings CS2 and CS5 may have the second threshold voltage distribution Vth2, and the first ground selection transistors GST0 of the fourth and sixth cell strings CS4 and CS6 may have the third threshold voltage distribution Vth3.

The second ground selection transistors GST1 of the first and sixth cell strings CS1 and CS6 may have the second threshold voltage distribution Vth2, the second ground selection transistors GST1 of the second and fourth cell strings CS2 and CS4 may have the first threshold voltage distribution Vth1, and the second ground selection transistors GST1 of the third and fifth cell strings CS3 and CS5 may have the third threshold voltage distribution Vth3.

The third ground selection transistors GST2 of the first and second cell strings CS1 and CS2 may have the third threshold voltage distribution Vth3, the third ground selection transistors GST2 of the third and fourth cell strings CS3 and CS4 may have the second threshold voltage distribution Vth2, and the third ground selection transistors GST2 of the fifth and sixth cell strings CS5 and CS6 may have the first threshold voltage distribution Vth1.

During a read operation of the semiconductor device according to the embodiment illustrated in FIGS. 14 and 16, a ground voltage Vss (or 0V) may be applied to the selected bit line BL, and when the first cell string CS1 is selected, a power supply voltage Vcc may be applied to the selected first string selection line SSL0, and the ground voltage Vss (or 0V) may be applied to the unselected string selection lines SSL1 to SSL5.

Additionally, a first read voltage Vread1 may be applied to the first ground selection line GSL0, a second read voltage Vread2 greater than the first read voltage Vread1 may be applied to the second ground selection line GSL1, and a third read voltage Vread3 greater than the second read voltage Vread2 may be applied to the third ground selection lines GSL2.

Under the voltage condition, all of the first to third ground selection transistors GST0 to GST2 of the first cell string CS1 may be turned on. The first ground selection transistor GST0 of the second cell string CS2 may be turned off, and the second ground selection transistor GST1 of the third cell string CS3 may be turned off. The first and second ground selection transistors GST0 and GST1 of the fifth cell string CS5 and the first ground selection transistors GST0 of the sixth cell string CS6 may be turned off.

Accordingly, when the first cell string CS1 in the selected bit line BL is electrically connected to the bit line BL and the common source line CSL, the unselected second, third, fourth, fifth, and sixth cell strings CS3, CS4, CS5, and CS6 may be electrically separated from the common source line CSL and the bit line BL by the first and second ground selection transistors GST0 and GST1.

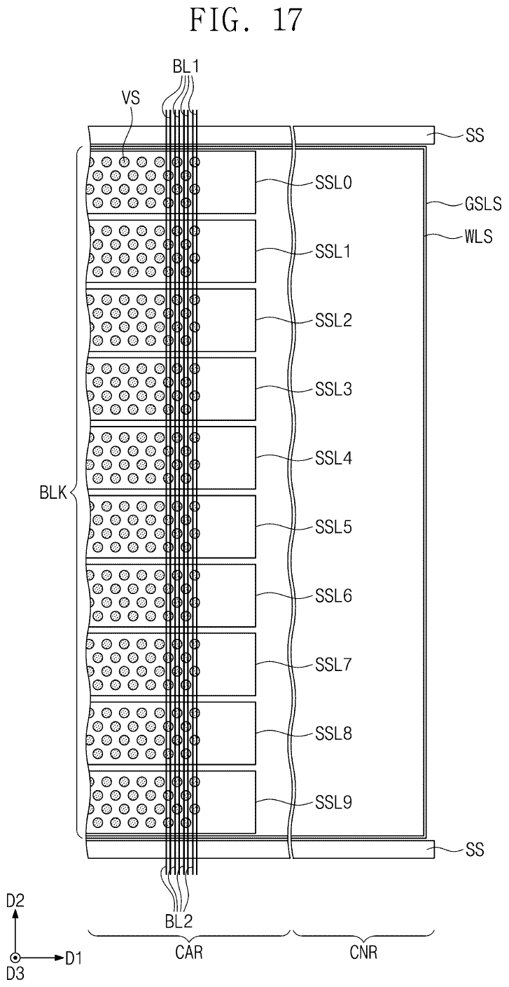

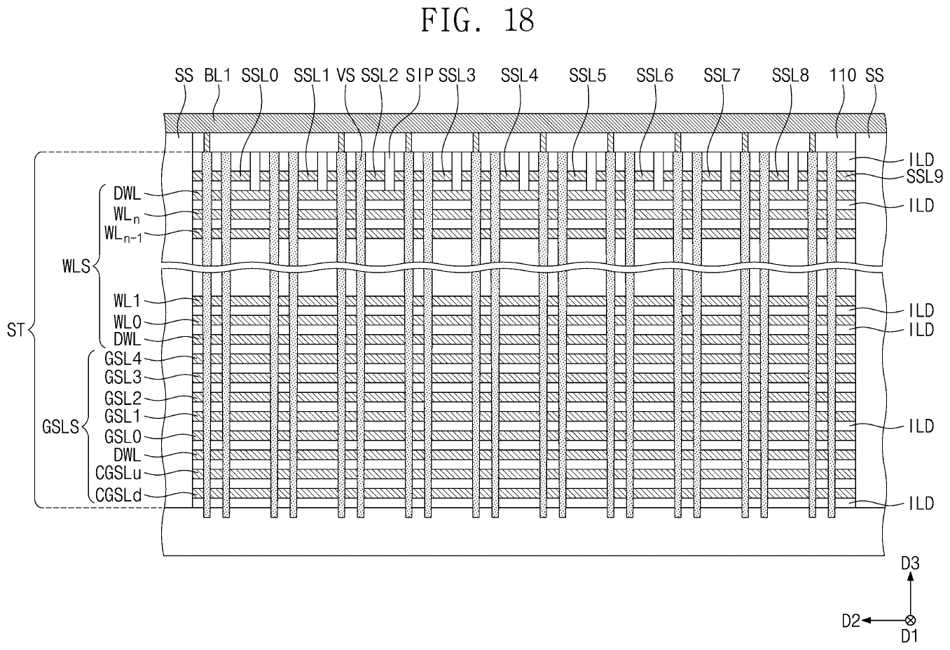

FIG. 17 is a plan view illustrating a portion of a memory cell array of a semiconductor device according to an embodiment of inventive concepts. FIG. 18 is a cross-sectional view of a semiconductor device according to an embodiment of inventive concepts. For the sake of simplicity of explanation, descriptions of technical features that are the same as those of the semiconductor device described above may be omitted, and differences will be described in detail.

Referring to FIGS. 17 and 18, as previously described with reference to FIGS. 7A and 8A, the stacked structure ST may be disposed between two adjacent separation structures SS. The stacked structure ST may include a ground selection structure GSLS, a word line structure WLS, and a string selection structure SSL0 to SSL9 sequentially stacked on the substrate 100.

As an example, a ground selection structure GSLS may include first to fifth ground selection lines GSL0 to GSLA vertically stacked on the substrate 100 with an interlayer insulating layer ILD interposed therebetween and may include upper and lower common ground selection lines CGSLu and CGSLd between the substrate 100 and the first ground selection line GSL0. Each of the first to tenth ground selection lines GSL0 to GSL9 may not be physically separated between the separation structures SS but may be a single layer in a form of a line.

Additionally, the stacked structure ST may include first to tenth string selection lines SSL0 to SSL9 that are horizontally spaced apart from each other on a word line structure WLS. The first to tenth string selection lines SSL0 to SSL9 may be spaced apart from each other in the second direction D2 by separation insulating patterns SIP disposed on the word line structure WLS. The first to tenth string selection lines SSL0 to SSL9 may overlap first to tenth ground selection lines GSL0 to GSL9, respectively, when viewed in a plan view.

The bit lines BL1 and BL2 may cross the stacked structure ST on the cell array region CAR. Each of the two bit lines BL1 and BL2 may be disposed on the vertical structures VS arranged in a row in the second direction D2. As an example, each bit line BL1 and BL2 may be electrically connected to 10 vertical structures VS.

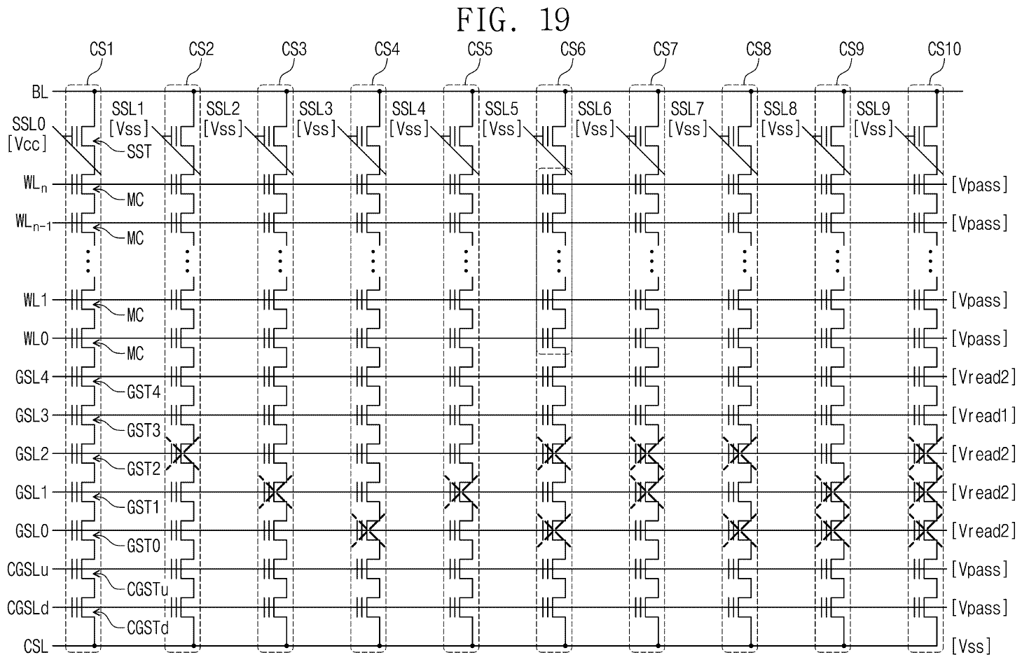

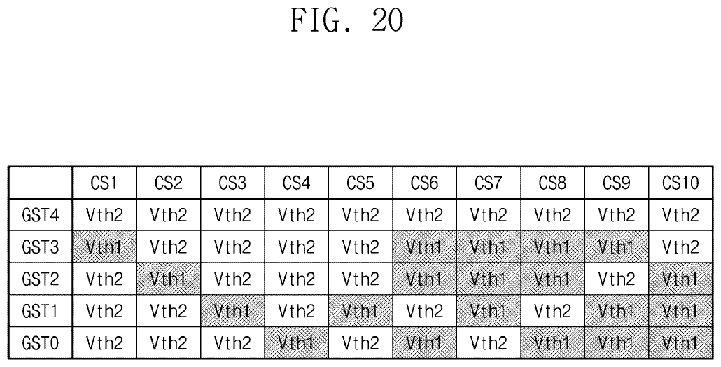

FIG. 19 is a circuit diagram illustrating a cell array of a semiconductor device according to embodiments of inventive concepts, and illustrates a voltage condition during a read operation. FIG. 20 is a table showing threshold voltages of ground selection transistors in the semiconductor device illustrated in FIG. 19.

Referring to FIGS. 19 and 20, in each memory block, first to tenth cell strings CS1 to CS10 may be connected to bit lines BL, respectively. Each of the first to tenth cell strings CS1 to CS10 may include a string selection transistor SST, a plurality of memory cells MC connected in series, a plurality of ground selection transistors GST0 to GST4 connected in series, and a common ground selection transistors CGSTu and CGSTd.

In detail, Each of the first to tenth cell strings CS1 to CS10 may include first to fifth ground selection transistors GST0 to GST4 and upper and lower common ground selection transistors CGSTu and CGSTd. According to some embodiments, as described with reference to FIG. 12, each of the first to tenth cell strings CS1 to CS10 may include dummy transistors DT between the memory cell MC and the ground selection transistor GST2, between the ground selection transistor GST0 and the common ground selection transistor CGST, and between the ground selection transistors GST0, GST1, and GST2.

The first to fifth ground selection transistors GST0 to GST4 of the first to tenth cell strings CS1 to CS10 may be controlled by the first to fifth ground selection lines GSL0 to GSLA, respectively.

As illustrated in FIG. 10, the first to fifth ground selection transistors GST0 to GST5 of each of the cell strings CS1 to CS10 may have a first threshold voltage distribution Vth1 or a second threshold voltage distribution Vth2 greater than the first threshold voltage distribution Vth1.

As an example, referring to FIG. 20, the first ground selection transistors GST0 of the first, second, third, fifth, and seventh cell strings CS1, CS2, CS3, CS5, and CS7 may have the second threshold voltage distribution Vth2, and the first ground selection transistors GST0 of the fourth, sixth, eighth, ninth, and tenth cell strings CS4, CS6, CS8, CS9, and CS10 may have the first threshold voltage distribution Vth1.

The second ground selection transistors GST1 of the first, second, fourth, sixth, and eighth cell strings CS1, CS2, CS4, CS6, and CS8 may have the second threshold voltage distribution Vth2, and the second ground selection transistors GST1 of the third, fifth, seventh, ninth, and tenth cell strings CS3, CS5, CS7, CS9, and CS10 may have the first threshold voltage distribution Vth1.

The third ground selection transistors GST2 of the first, third, fourth, fifth, and ninth cell strings CS1, CS3, CS4, CS5, and CS9 may have the second threshold voltage distribution Vth2, and the third ground selection transistors GST2 of the second, sixth, seventh, eighth, and tenth cell strings CS2, CS6, CS7, CS8, and CS10 have the first threshold voltage distribution Vth1.

The fourth ground selection transistors GST3 of the second, third, fourth, fifth, and tenth cell strings CS2, CS3, CS4, CS5, and CS10 may have the second threshold voltage distribution Vth2, and the fourth ground selection transistors GST3 of the first, sixth, seventh, eighth, and ninth cell strings CS1, CS6, CS7, CS8, and CS9 have the first threshold voltage distribution Vth1.

The fourth ground selection transistors GST3 of the first to tenth cell strings CS1 to CS10 may have the second threshold voltage distribution Vth2.

During a read operation of the semiconductor device according to the embodiment illustrated in FIGS. 19 and 20, a ground voltage Vss (or 0V) may be applied to the selected bit line BL, and when the first cell string CS1 is selected, a power supply voltage Vcc may be applied to the selected first string selection line SSL0, and the ground voltage Vss (or 0V) may be applied to the unselected string selection lines SSL1 to SSL5. Additionally, a first read voltage Vread1 may be applied to the third ground selection line (GSL2), and a second read voltage Vread2 greater than the first read voltage Vread1 may be applied to the first, second, and fourth ground selection lines GSL0, GSL1, and GSL3.

Under the voltage condition, all of the first to fifth ground selection transistors GST0 to GST4 of the first cell string CS1 may be turned on.

The unselected second to tenth cell strings CS2 to CS10 may be electrically separated from the common source line CSL and the bit line BL by the first to fourth ground selection transistors GST0 to GST3.

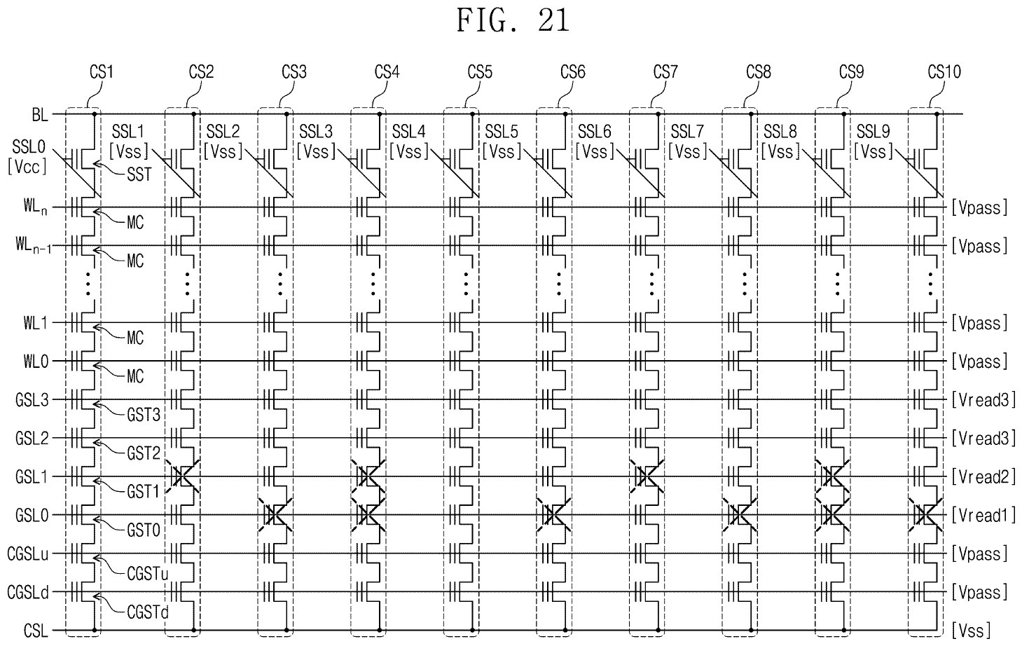

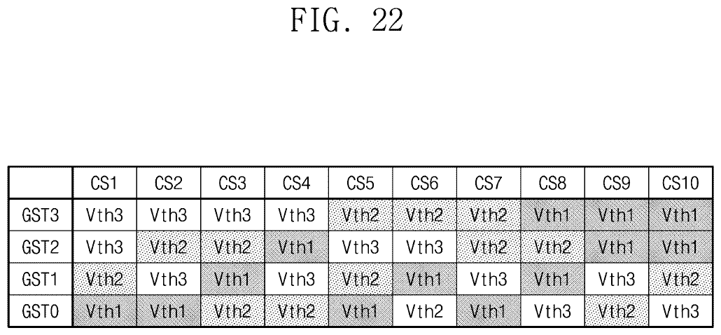

FIG. 21 is a circuit diagram illustrating a cell array of a semiconductor device according to embodiments of inventive concepts, and illustrates voltage conditions during a read operation. FIG. 22 is a table showing threshold voltages of ground selection transistors in the semiconductor device illustrated in FIG. 21.

Referring to FIGS. 21 and 22, in each memory block, first to tenth cell strings CS1 to CS10 may be connected to bit lines BL, respectively. Each of the first to tenth cell strings CS1 to CS10 may include a string selection transistor SST, a plurality of memory cells MC connected in series, first to fourth ground selection transistors GST0 to GST3, and an upper and lower common ground selection transistors CGSTu and CGSTd.

The first to fourth ground selection transistors GST0 to GST3 of the first to tenth cell strings CS1 to CS10 may be controlled by the first to fourth ground selection lines GSL0 to GSL3, respectively.

As illustrated in FIG. 15, the first to fourth ground selection transistors GST0 to GST3 of each of the cell strings CS1 to CS10 may have a first threshold voltage distribution Vth1, a second threshold voltage distribution Vth2 greater than the first threshold voltage distribution Vth1, or a third threshold voltage distribution Vth3 greater than the second threshold voltage distribution Vth2.

As an example, referring to FIG. 22, the first ground selection transistors GST0 of the first, second, fifth, and seventh cell strings CS1, CS2, CS5, and CS7 may have the first threshold voltage distribution Vth1, the first ground selection transistors GST0 of the third, fourth, sixth, and ninth cell strings CS3, CS4, CS6, and CS9 may have the second threshold voltage distribution Vth2, and the first ground selection transistors GST0 of the eighth and tenth cell strings CS8 and CS10 may have the third threshold voltage distribution Vth3.

The second ground selection transistors GST1 of the third, sixth, and eighth cell strings CS3, CS6, and CS8 may have the first threshold voltage distribution Vth1, the second ground selection transistors GST1 of the first, fifth, and tenth cell strings CS1, CS5, and CS10 may have the second threshold voltage distribution Vth2, and the second ground selection transistors GST1 of the second, fourth, seventh, and ninth cell strings CS2, CS4, CS7, and CS9 may have the third threshold voltage distribution Vth3.

The third ground selection transistors GST2 of the fourth, ninth, and tenth cell strings CS4, CS9, and CS10 may have the first threshold voltage distribution Vth1, the third ground selection transistors GST2 of the second, third, seventh, and eighth cell strings CS2, CS3, CS7, and CS8 may have the second threshold voltage distribution Vth2, and the third ground selection transistors GST2 of the first, fifth, and sixth cell strings CS1, CS5, and CS6 may have the third threshold voltage distribution Vth3.

The fourth ground selection transistors GST3 of the 8th, 9th, and 10th cell strings CS4, CS9, and CS10 may have the first threshold voltage distribution Vth1, the fourth ground selection transistors GST3 of the fifth, sixth, seventh, and cell strings CS5, CS6, and CS7 may have the second threshold voltage distribution Vth2, and the fourth ground selection transistors GST3 of the first to fourth cell strings CS1 to CS4 may have the third threshold voltage distribution Vth3.

During a read operation of the semiconductor device according to the embodiment shown in FIGS. 21 and 22, a ground voltage Vss (or 0V) may be applied to the selected bit line BL, and when the first cell string CS1 is selected, a power supply voltage Vcc may be applied to the selected first string selection line SSL0, and the ground voltage Vss (or 0V) may be applied to the unselected string selection lines SSL1 to SSL5.

Additionally, a first read voltage Vread1 may be applied to the first ground selection line GSL0, a second read voltage Vread2 greater than the first read voltage Vread1 may be applied to the second ground selection line GSL1, and a third read voltage Vread3 greater than the second read voltage Vread2 may be applied to the third and fourth ground selection lines GSL2 and GSL3.

Under the voltage condition, all of the first to fifth ground selection transistors GST0 to GST4 of the first cell string CS1 may be turned on.

The unselected second, third, fourth, sixth to tenth cell strings CS2, CS3, CS4, CS6 to CS10 may be electrically separated from the common source line CSL and the bit line BL by the first to fourth ground selection transistors GST0 to GST3. In the case of the fifth cell string CS5, the first to fifth ground selection transistors GST0 to GST4 may all be turned on, and the string selection transistor SST of the fifth cell string CS5 may be turned off, and thus the fifth cell string CS5 may be electrically separated from the selected bit line BL.

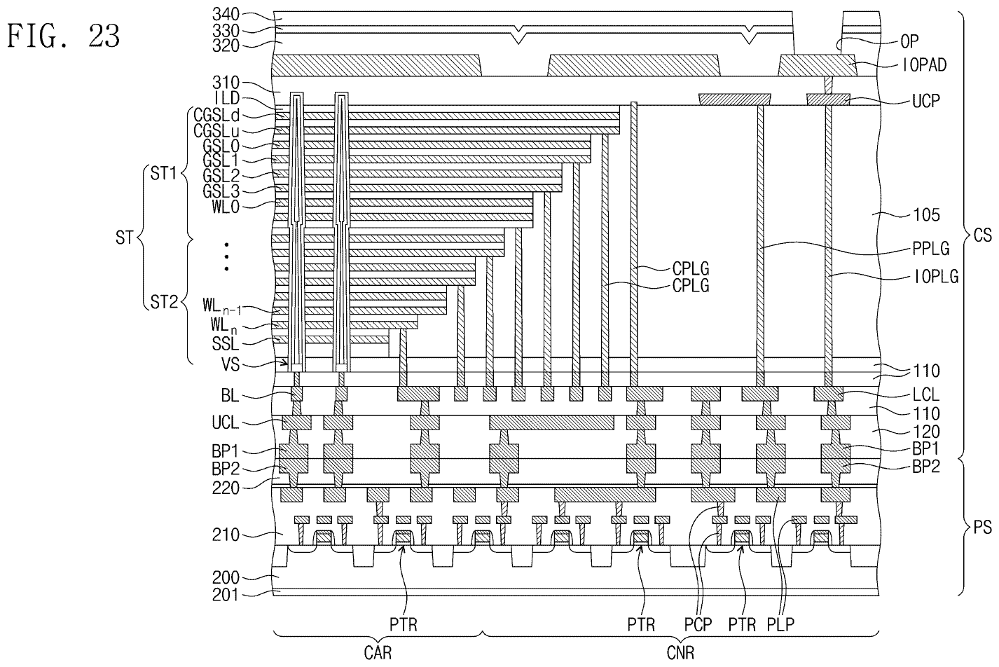

FIG. 23 is a cross-sectional view of a semiconductor device according to an embodiment of inventive concepts.

Referring to FIG. 23, a semiconductor device according to an embodiment of inventive concepts may include a peripheral circuit structure PS on a semiconductor substrate 200 and a cell array structure CS on the peripheral circuit structure PS.

According to embodiments, as the cell array structure CS is combined on the peripheral circuit structure PS, cell capacity per unit area of the semiconductor device according to embodiments of inventive concepts may be increased. In addition, as the peripheral circuit structure PS and the cell array structure CS are separately manufactured and are combined with each other, damage to peripheral circuits PTR due to various heat treatment processes may be prevented, thereby improving electrical characteristics and reliability of the semiconductor device according to inventive concepts.

The cell array structure CS may include a memory cell array including memory cells arranged three-dimensionally.

The cell array structure CS of the semiconductor device may include a cell array region CAR and a connection region CNR, and the connection region CNR may be adjacent to the cell array region CAR.

The cell array structure CS may include a stacked structure ST, vertical structures VS, bit lines BL, cell contact plugs CPLG, peripheral contact plugs PPLG, and input/output contact plugs IOPLG.

The stacked structure ST of the cell array structure CS may be provided in plural. The plurality of stacked structures ST may extend in the first direction D1 and be spaced apart from each other in a second direction D2 when viewed in a plan view according to FIG. 7A. Hereinafter, for convenience of explanation, a single stacked structure ST will be described, but the following description may be equally applied to other stacked structures ST.

As previously described with reference to FIGS. 7A, 7B, 8A, and 8B, the stacked structure ST may include stacked ground selection lines CGSLd, CGSLu, GSL0 to GSL3 and word lines WL0 to WLn, and string selection lines SSL.

In embodiments, the stacked structure ST may include a first stacked structure ST1 and a second stacked structure ST2 on the first stacked structure ST1. The first stacked structure ST1 may include some of the ground selection lines CGSLd, CGSLu, GSL0 to GSL3 and word lines WL0 to WLn. The second stacked structure ST2 may include other portions of the word lines WL0 to WLn and string selection lines SSL.

The second stacked structure ST2 may be disposed between the first stacked structure ST1 and the peripheral circuit structure PS. The lowest one of the conductive lines of the second stacked structure ST2 may have the smallest length in the first direction D1, and the uppermost one of the conductive lines of the first stacked structure ST1 may have the greatest length in the first direction D1.

The conductive lines of the stacked structure ST may be stacked to have an inverted staircase structure in the connection region CNR. Each of the conductive lines may include a pad portion in the connection region CNR. The pad portions of the conductive lines may be positioned at different positions horizontally and vertically. The cell contact plugs CPLG may be respectively connected to the pad portions of the conductive lines.

A plurality of vertical structures VS may penetrate the stacked structure ST in the cell array region CAR. When viewed in a plan view, the vertical structures VS may be arranged in one direction or arranged in a zigzag shape. The vertical structures VS may be provided to penetrate the stacked structure ST also in the connection region CNR.

In embodiments, each of the vertical structures VS may be provided in a vertical channel hole penetrating the stacked structure ST. In embodiments, the vertical channel hole may include first vertical channel holes penetrating the first stacked structure ST1, and second vertical channel holes penetrating the second stacked structure ST2 and connected to the first vertical channel holes, respectively.

Each of the vertical structures VS may include a first vertical extension in a first vertical channel hole and a second vertical extension in a second vertical channel hole. The first vertical extension portion and the second vertical extension portion may be one structure that extends continuously without an interface. Here, the first vertical extension may have a sidewall with a uniform slope from bottom to top thereof. Likewise, the second vertical extension may have a sidewall with a uniform slope from bottom to top thereof. That is, a width of each of the first and second vertical extensions in the first direction D1 or the second direction D2 may decrease as a distance from the semiconductor substrate 200 increases. A portion where the first vertical extension and the second vertical extension are connected to each other may have different diameters. A step may be formed at the portion where the first vertical extension and the second vertical extension are connected to each other.

However, inventive concepts are not limited thereto, and unlike illustrated, each first vertical structure VS1 may have three or more vertical extensions each having a step at two or more interfaces. As another example, each first vertical structure VS1 may have a flat sidewall without any steps.

A bit line conductive pad may be formed at a lower end of each vertical structure VS, and the bit line BL may be connected to the bit line conductive pad through a bit line contact plug.

In the connection region CNR, the cell contact plugs CPLG may penetrate an upper insulating layers 110 and a flat insulating layer 105 to be connected to the pad portions of the conductive lines, respectively. Vertical lengths of the cell contact plugs CPLG may be reduced as the cell contact plugs become adjacent to the cell array region CAR. Upper surfaces of the cell contact plugs CPLG may be substantially coplanar.

The peripheral contact plugs PPLG and the input/output contact plugs IOPLG may be connected to upper conductive patterns UCP by penetrating the upper insulating layers 110 and the flat insulating layer 105 in the connection region CNR.

Each of the cell, peripheral, and input/output contact plugs CPLG, PPLG, ad IOPLG may include a barrier metal layer including a conductive metal nitride (e.g., titanium nitride, tantalum nitride, etc.), and a metal layer including a metal (e.g., tungsten, titanium, tantalum, etc.).

Upper and lower conductive lines LCL and UCL may be disposed in the upper insulating layers 110, and the upper and lower conductive lines LCL and UCL may be electrically connected to the bit lines BL, cells, peripherals, and input/output contact plugs CPLG, PPLG, and IOPLG.

The upper and lower conductive lines LCL and UCL may include at least one of a metal (e.g., tungsten, copper, aluminum, etc.), a conductive metal nitride (e.g., titanium nitride, tantalum nitride, etc.), or a transition metal (e.g., titanium, tantalum, etc.).

First bonding pads BP1 may be disposed in an uppermost insulating layer 120. The first bonding pads BP1 may be electrically connected to the upper conductive lines UCL. The first bonding pads BP1 may be formed of aluminum, copper, or tungsten.

The peripheral circuit structure PS including second bonding pads BP2 may be disposed under the cell array structure CS.

In detail, the peripheral circuit structure PS may include a semiconductor substrate 200, peripheral circuits PTR that control the memory cell array, and peripheral interlayer insulating layers 210 and 220 covering the peripheral circuits PTR. The peripheral circuits PTR may be integrated on an upper surface of the semiconductor substrate 200. A surface insulating layer 201 may be provided on a back surface of the semiconductor substrate 200.

The semiconductor substrate 200 may be, for example, a silicon substrate, a silicon-germanium substrate, a germanium substrate, or a single crystalline epitaxial layer grown on a monocrystalline silicon substrate. The semiconductor substrate 200 may have an upper surface parallel to the first direction D1 and the second direction D2 that intersects the first direction D1, and orthogonal to the third direction D3. For example, the first to third directions D1, D2, and D3 may be directions orthogonal to each other.

The peripheral circuits PTR may be row and column decoders, page buffers, and control circuits. In detail, the peripheral circuits PTR may include NMOS and PMOS transistors. Peripheral circuit wirings PLP may be electrically connected to the peripheral circuits PTR through peripheral contact plugs PCP.

For example, a width of the peripheral contact plugs PCP may increase in the first direction D1 or the second direction D2 toward the third direction D3. The peripheral contact plugs PCP and peripheral circuit wirings PLP may include a conductive material such as metal.

Peripheral interlayer insulating layers 210 and 220 may be provided on the upper surface of the semiconductor substrate 200. The peripheral interlayer insulating layers 210 and 220 may cover the peripheral circuits PTR, peripheral contact plugs PCP, and peripheral circuit wirings PLP on the semiconductor substrate 200. The peripheral contact plugs PCP and peripheral circuit wirings PLP may be electrically connected to peripheral circuits PTR. The peripheral interlayer insulating layers 210 and 220 may include a silicon oxide layer, a silicon nitride layer, a silicon oxynitride layer, and/or a low dielectric layer.

The second bonding pads BP2 may be disposed in the uppermost peripheral interlayer insulating layer 220. The peripheral interlayer insulating layer 220 may not cover upper surfaces of the second bonding pads BP2. An upper surface of the uppermost peripheral interlayer insulating layer 220 may be substantially coplanar with the upper surfaces of the second bonding pads BP2. The second bonding pads BP2 may be electrically connected to the peripheral circuits PTR through peripheral circuit wirings PLP and peripheral contact plugs PCP.

The second bonding pads BP2 may be electrically and physically connected to the first bonding pads BP1 through a bonding manner. That is, the second bonding pads BP2 may be in direct contact with the first bonding pads BP1.

The second bonding pads BP2 may include the same metal material as the first bonding pads BP1. The second bonding pads BP2 may have substantially the same shape, same width, or same area as those of the first bonding pads BP1.

An upper insulating layer 310 may be disposed on the stacked structure ST of the cell array structure CS. The upper insulating layer 310 may cover the stacked structure ST and the upper conductive patterns UCP. Input/output pads IOPAD may be disposed on the upper insulating layer 310. The input/output pads IOPAD may be electrically connected to the input/output contact plugs IOPLG. The input/output pads IOPAD may be electrically connected to the peripheral circuits PTR of the peripheral circuit structure PS through the input/output contact plugs IOPLG.

A capping insulating layer 320 may be disposed on the upper insulating layer 310, and the capping insulating layer 320 may cover the input/output pads IOPAD.

A capping insulating layer 320, an interlayer film 330 (e.g., dielectric film, hard mask layer) and a passivation layer 340 may be sequentially formed on the entire surface of the upper insulating layer 310. The capping insulating layer 320 may be, for example, a silicon nitride layer or a silicon oxynitride layer. The passivation layer 340 may be, for example, a polyimide-based material such as photo sensitive polyimide (PSPI).

The capping insulating layer 320, interlayer film 330, and the passivation layer 340 may have a pad opening OP that exposes a portion of the input/output pads IOPAD.

According to embodiments of inventive concepts, the semiconductor device may share the single ground selection line that is not physically separated in one memory block and may include the ground selection transistors having the different threshold voltages.

As the ground selection transistors positioned at the same level or in the same plane share one ground selection line that is not physically separated, the process or structure for physically separating the ground selection line may be omitted. Therefore, the integration and productivity of the semiconductor device may be further improved.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While embodiments are described above, a person skilled in the art may understand that many modifications and variations are made without departing from the spirit and scope of inventive concepts defined in the following claims. Accordingly, the example embodiments of inventive concepts should be considered in all respects as illustrative and not restrictive, with the spirit and scope of inventive concepts being indicated by the appended claims.

What is claimed is:

1. A semiconductor device comprising:
a substrate;
a plurality of cell strings disposed perpendicular to an upper surface of the substrate; and
a bit line connected to at least six of the plurality of cell strings, wherein
each of the plurality of cell strings includes a plurality of memory cells connected in series to each other in a direction perpendicular to the upper surface of the substrate, a first ground selection transistor to a fourth ground selection transistor connected in series to each other between the plurality of memory cells and the substrate, and a string selection transistor between the plurality of memory cells and the bit line,
based on the string selection transistor and the first ground selection transistor to the fourth ground selection transistor in each of the plurality of cell strings, the plurality of cell strings provide a plurality of string selection transistors, a plurality of first ground selection transistors, a plurality of second ground selection transistors, a plurality of third ground selection transistors, and a plurality of fourth ground selection transistors,
the plurality of string selection transistors of the plurality of cell strings are electrically separated from each other,
the plurality of first ground selection transistors in the plurality of cell strings are configured to be controlled in common,
the plurality of second ground selection transistors in the plurality of cell strings are configured to be controlled in common,
the plurality of third ground selection transistors in the plurality of cell strings are configured to be controlled in common,
the plurality of fourth ground selection transistors in the plurality of cell strings are configured to be controlled in common,
a first one of the plurality of first ground selection transistors to the plurality of fourth ground selection transistors has a first threshold voltage distribution,
a second one of the plurality of first ground selection transistors to the plurality of fourth ground selection transistors has a second threshold voltage distribution, and
the second threshold voltage distribution is different from the first threshold voltage distribution.

2. The semiconductor device of claim 1, wherein at least two of the plurality of first ground selection transistors to the plurality of fourth ground selection transistors have the first threshold voltage distribution.

3. The semiconductor device of claim 1, further comprising:
a first ground selection line, a second ground selection line, a third ground selection line, and a fourth ground selection line that are vertically stacked on the substrate, wherein
each of the first ground selection line, the second ground selection line, the third ground selection line, and the fourth ground selection line is a single conductive pattern extending in a first direction,
the first direction is parallel to the upper surface of the substrate, and
the first ground selection line, the second ground selection line, the third ground selection line, and the fourth ground selection line are connected to the plurality of first ground selection transistors, the plurality of second ground selection transistors, the plurality of third ground selection transistors, and the plurality of fourth ground selection transistors, respectively.

4. The semiconductor device of claim 3, further comprising:
a first separation structure and a second separation structure on the substrate and extending in the first direction, wherein
the first ground selection line, the second ground selection line, the third ground selection line, and the fourth ground selection line are between the first separation structure and the second separation structure.

5. The semiconductor device of claim 4, further comprising:
a plurality of string selection lines spaced apart from each other with a regular interval between the first separation structure and the second separation structure, wherein
the plurality of string selection lines are positioned at a same level from the substrate.

6. The semiconductor device of claim 5, wherein
a width of the first ground selection line, a width of the second ground selection line, a width of the third ground selection line, and a width of the fourth ground selection line each are greater than a sum of widths of at least six of the plurality of string selection lines.

7. The semiconductor device of claim 1, wherein
each of the plurality of cell strings further includes a common ground selection transistor connected in series to each other between the substrate and the first ground selection transistor.

8. The semiconductor device of claim 7, wherein
based on the common ground selection transistor in each of the plurality of cell strings, the plurality of cell strings provide a plurality of common ground selection transistors having a same threshold voltage distribution.

9. The semiconductor device of claim 7, wherein each corresponding cell string of the plurality of cell strings further includes at least two dummy transistors connected in series to each other between the common ground selection transistor and the first ground selection transistor of the corresponding cell string.

10. The semiconductor device of claim 1, further comprising:
a semiconductor substrate;
a peripheral circuit structure including peripheral circuits integrated on the semiconductor substrate and first bonding pads connected to the peripheral circuits; and
second bonding pads bonded to the first bonding pads,
wherein the second bonding pads are electrically connected to the plurality of cell strings.

11. A semiconductor device comprising:
a substrate;
a plurality of cell strings perpendicular to an upper surface of the substrate; and
a bit line connected to at least six of the plurality of cell strings, wherein
each of the plurality of cell strings includes a plurality of memory cells connected in series to each other in a direction perpendicular to the upper surface of the substrate, a plurality of ground selection transistors connected in series to each other between the plurality of memory cells and the substrate, and a string selection transistor between the plurality of memory cells and the bit line,
in each of the plurality of cell strings, the plurality of ground selection transistors include a first ground selection transistor having a first threshold voltage distribution, a second ground selection transistor having a second threshold voltage distribution, and a third ground selection transistor having a third threshold voltage distribution, and
the first threshold voltage distribution, the second threshold voltage distribution, and the third threshold voltage distribution are different from each other.

12. The semiconductor device of claim 11, wherein
the second threshold voltage distribution is greater than the first threshold voltage distribution, and
the third threshold voltage distribution is greater than the second threshold voltage distribution.

13. The semiconductor device of claim 11, wherein
the string selection transistor of each of the plurality of cell strings provides a plurality of string selection transistors,
the plurality of string selection transistors of the cell strings are electrically separated from each other, and
the ground selection transistors positioned at a same level in the plurality of cell strings are configured to be commonly controlled.

14. The semiconductor device of claim 11, further comprising:
a first ground selection line, a second ground selection line, and a third ground selection line that are vertically stacked on the substrate, wherein
the first ground selection transistor, the second ground selection transistor, and the third ground selection transistor of each of the plurality of cell strings provide a plurality of first ground selection transistors, a plurality of second ground selection transistors, and a plurality of third ground selection transistors,
each of the first ground selection line, the second ground selection line, and the third ground selection line are commonly connected to at least one of the plurality of first ground selection transistors, at least one of the plurality of second ground selection transistors, and at least one of the plurality of third ground selection transistors.

15. The semiconductor device of claim 11, further comprising:
a first separation structure and a second separation structure on the substrate and extending in a first direction;
a first ground selection line, a second ground selection line, and a third ground selection line that are vertically stacked on the substrate and between the first separation structure and the second separation structure; and
a plurality of string selection lines horizontally spaced apart from each other between the first separation structure and the second separation structure, wherein
each of the first ground selection line, the second ground selection line, and the third ground selection line is a single conductive pattern extending in the first direction, and
the first direction is parallel to the upper surface of the substrate.

16. The semiconductor device of claim 15, further comprising:
a plurality of word lines that are vertically stacked between the third ground selection line and the plurality of string selection lines, wherein
each of the plurality of word lines is commonly connected to the memory cells positioned at a same level in the plurality of cell strings.

17. The semiconductor device of claim 11, wherein
each of the plurality of cell strings further includes a common ground selection transistor connected in series to each other between the substrate and the first ground selection transistor.

18. The semiconductor device of claim 17, wherein each of the plurality of cell strings further includes at least two dummy transistors connected in series to each other between the common ground selection transistor and the first ground selection transistor.

19. An electronic system comprising:
a semiconductor device including a peripheral circuit structure and a cell array structure on the peripheral circuit structure; and
a controller electrically connected to the semiconductor device through an input/output pad and configured to control the semiconductor device, wherein
the cell array structure includes a substrate, a plurality of cell strings disposed perpendicular to an upper surface of the substrate, and a bit line connected to at least six of the plurality of cell strings,
each of the plurality of cell strings includes a plurality of memory cells connected in series to each other in a direction perpendicular to the upper surface of the substrate, a first ground selection transistor to a fourth ground selection transistor connected in series to each other between the plurality of memory cells and the substrate, and a string selection transistor between the plurality of memory cells and the bit line,
based on the string selection transistor and the first ground selection transistor to the fourth ground selection transistor in each of the plurality of cell strings, the plurality of cell strings provide a plurality of string selection transistors, a plurality of first ground selection transistors, a plurality of second ground selection transistors, a plurality of third ground selection transistors, and a plurality of fourth ground selection transistors,
the plurality of string selection transistors of the plurality of cell strings are electrically separated from each other,
the plurality of first ground selection transistors in the plurality of cell strings are configured to be controlled in common,
the plurality of second ground selection transistors in the plurality of cell strings are configured to be controlled in common,
the plurality of third ground selection transistors in the plurality of cell strings are configured to be controlled in common,
the plurality of fourth ground selection transistors in the plurality of cell strings are configured to be controlled in common,
a first one of the plurality of first ground selection transistors to the plurality of fourth ground selection transistors has a first threshold voltage distribution,
a second one of the plurality of first ground selection transistors to the plurality of fourth ground selection transistors has a second threshold voltage distribution, and
the second threshold voltage distribution is different from the first threshold voltage distribution.

20. The electronic system of claim 19, wherein
the cell array structure further includes a first separation structure and a second separation structure on the substrate and a plurality of string selection lines horizontally spaced apart from each other between the first separation structure and the second separation structure,
the first separation structure and the second separation structure extend in a first direction,
a first ground selection line, a second ground selection line, and a third ground selection line that are vertically stacked on the substrate, wherein
the first ground selection line, the second ground selection line, and the third ground selection line are between the first separation structure and the second separation structure.
each of the first ground selection line, the second ground selection line, and the third ground selection line is a single conductive pattern extending in the first direction,
the first direction is parallel to the upper surface of the substrate, and
the first ground selection line, the second ground selection line, and the third ground selection line are connected to the plurality of first ground selection transistors, the plurality of second ground selection transistors, and the plurality of third ground selection transistors, respectively.
